(19) United States
(12) Patent Application Publication
(10) Pub. No.: US 2024/0224483 A1
(43) Pub. Date: Jul. 4, 2024

(54) ELECTRONIC DEVICE WITH ELECTROMAGNET

(71) Applicant: Advanced Semiconductor Engineering, Inc., Kaohsiung (TW)

(72) Inventor: Chin Han CHEN, Kaohsiung (TW)

(73) Assignee: Advanced Semiconductor Engineering, Inc., Kaohsiung (TW)

(21) Appl. No.: 18/090,438

(22) Filed: Dec. 28, 2022

(51) Int. Cl. H05K 9/00

(52) U.S. Cl. CPC H05K 9/0088

(57) ABSTRACT

An electronic device includes a coil element configured to provide an electromagnetic field, a housing with an EMI shielding layer covering the coil element and a barrier configured to block an electromagnetic induction effect caused by the electromagnetic field and the EMI shielding layer.

### BACKGROUND

### 1. Field of the Disclosure

The instant disclosure relates to, amongst other things, an electronic device with an electromagnet. The electronic device includes a charging unit.

### 2. Description of Related Art

An electronic device, which includes an electromagnet used for charging an external device, such as an earphone, a hearing aid, etc., should include a metal cover or a cover with a metal layer to cover the electromagnet, so that an electromagnetic field from the electromagnet could be blocked. However, the electromagnetic field provided from the electromagnet and the metal cover create an electromagnetic induction effect and thus generate the eddy current. Thus, the inductance and quality factor of the electromagnet are decreased and the charge efficiency of the electronic device is reduced.

### SUMMARY

According to one example embodiment of the instant disclosure, an electronic device includes a coil element, a surrounding structure with an EMI (Electromagnetic Interference) shielding layer covering the coil element and a barrier configured to block an electromagnetic induction effect caused by an electromagnetic field provided from the coil element and the EMI shielding layer.

According to another example embodiment of the instant disclosure, an electronic device includes a coil element and a surrounding structure surrounding the coil element. The surrounding structure includes a first conductive layer with a plurality of separated portions. The separated portions are configured to reduce an eddy current caused by an electromagnetic field provided from the coil element and the surrounding structure.

According to another example embodiment of the instant disclosure, an electronic device includes a charging element, a magnetic barrier structure and a conductive structure. The magnetic barrier structure is disposed between the charging element and the conductive structure. The charging element is configured to provide a magnetic field and charge an external device received in the electronic device, and the conductive structure is configured to provide a shielding cap.

In order to further understanding of the instant disclosure, the following embodiments are provided along with illustrations to facilitate appreciation of the instant disclosure; however, the appended drawings are merely provided for reference and illustration, and do not limit the scope of the instant disclosure.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1A is an exploded view of an electronic device in accordance with an embodiment of the instant disclosure.

FIG. 1B is a top view of an electronic device in accordance with an embodiment of the instant disclosure.

FIG. 1C illustrates a schematic cross-sectional view along line A-A in FIG. 1B.

FIG. 2 is a schematic cross-sectional view of an electronic device in accordance with an embodiment of the instant disclosure.

FIG. 3 is a schematic cross-sectional view of an electronic device in accordance with an embodiment of the instant disclosure.

FIG. 4 is a schematic cross-sectional view of an electronic device in accordance with an embodiment of the instant disclosure.

FIG. 5A is a schematic cross-sectional view of an electronic device in accordance with an embodiment of the instant disclosure.

FIG. 5B illustrates a schematic cross-sectional view along line B-B in FIG. 5A.

FIG. 6 is a schematic cross-sectional view of an electronic device in accordance with an embodiment of the instant disclosure.

FIG. 7 is a schematic cross-sectional view of an electronic device in accordance with an embodiment of the instant disclosure.

FIG. 8A is a top view of an electronic device in accordance with an embodiment of the instant disclosure.

FIG. 8B illustrates a schematic cross-sectional view along line C-C in FIG. 8A.

FIG. 9 is a schematic cross-sectional view of an electronic device in accordance with an embodiment of the instant disclosure.

FIG. 10 is an exploded view of an electronic device in accordance with an embodiment of the instant disclosure.

FIG. 11 is a schematic cross-sectional view of an electronic device in accordance with an embodiment of the instant disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features are formed or disposed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, spatially relative terms, such as “beneath,” “below,” “above,” “over,” “on,” “upper,” “lower,” “left,” “right,” “vertical,” “horizontal,” “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

Present disclosure provides an electronic device with an electromagnet, which includes a barrier configured to block an electromagnetic induction effect caused by an electromagnetic field provided from the electromagnet and the EMI (Electromagnetic Interference) shielding layer of the surrounding structure.

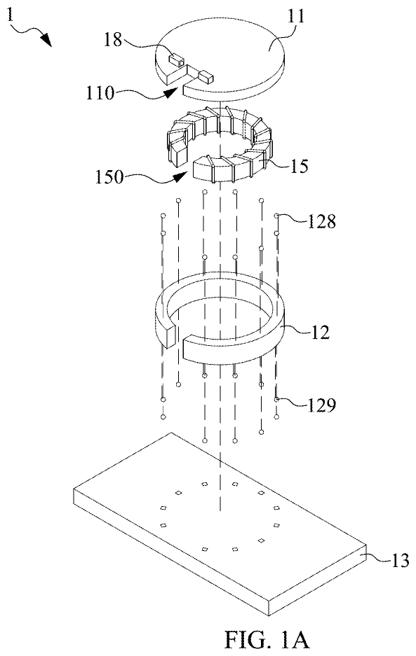

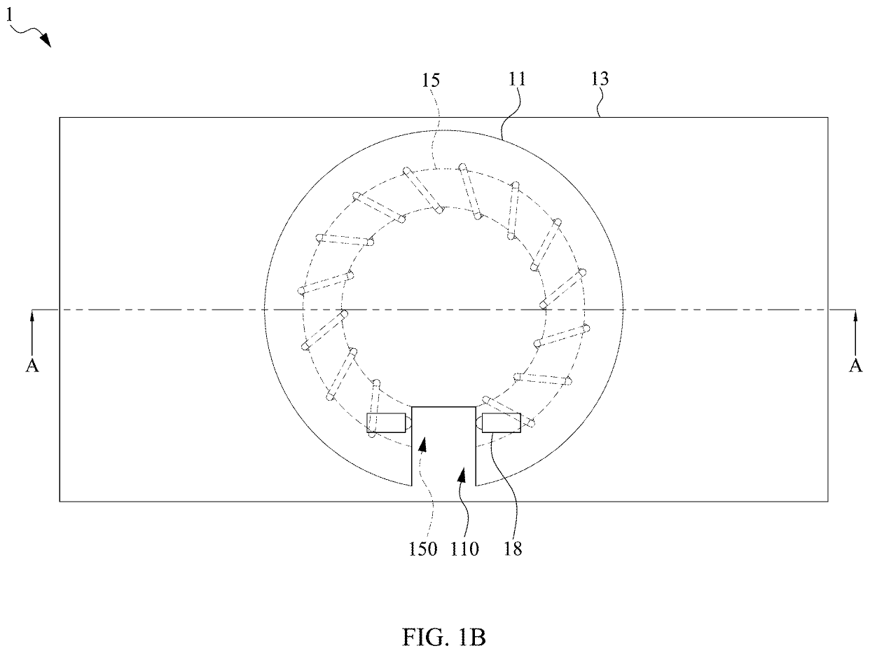

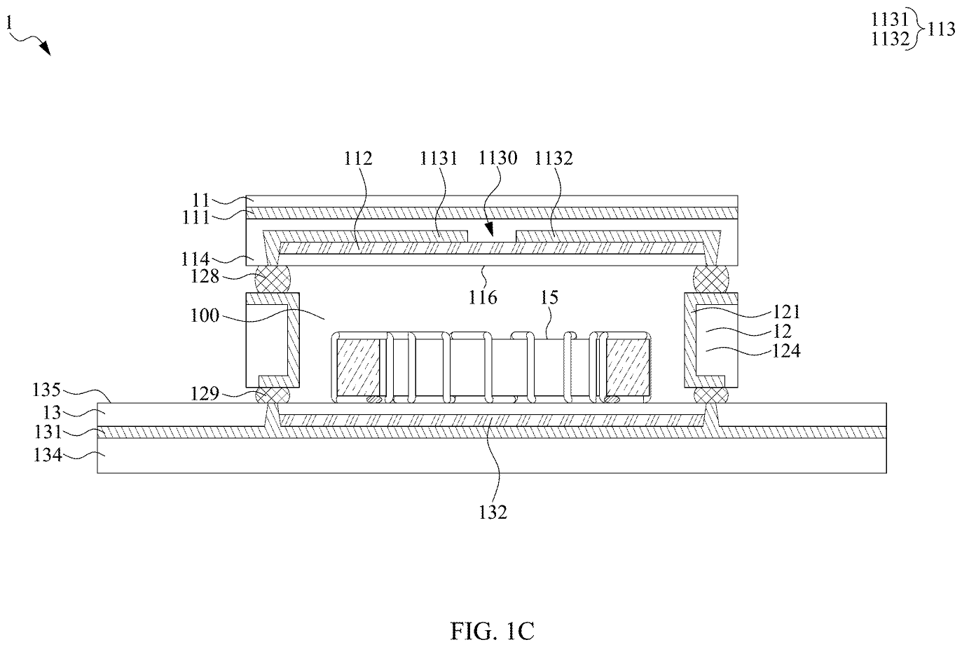

FIG. 1A is an exploded view of an electronic device 1 in accordance with an embodiment of the instant disclosure. FIG. 1B is a top view of an electronic device 1 in accordance with an embodiment of the instant disclosure. Referring to FIGS. 1A and 1B, the electronic device 1 may include a printed circuit board 11 (e.g., an upper circuit board), an interposer 12, a printed circuit board 13 (e.g., a lower circuit board) and a charging element 15. The interposer 12 is stacked on the printed circuit board 13 and the printed circuit board 11 is stacked on the interposer 12. That is, the interposer 12 is disposed on the printed circuit board 13 and supports the printed circuit board 11. As the interposer 12 is stacked on the printed circuit board 13 and the printed circuit board 11 is stacked on the interposer 12, the printed circuit board 11, the interposer 12 and the printed circuit board 13 may define an inner space. Further, the charging element 15 may be arranged within the inner space defined by the printed circuit board 11, the interposer 12 and the printed circuit board 13. In some embodiments of the present disclosure, the inner space cooperatively defined by the printed circuit board 11, the interposer 12 and the printed circuit board 13 may include a package body surrounding the charging element 15. Referring to FIGS. 1A and 1B, an area of the printed circuit board 13 may be larger than an area of the printed circuit board 11. In other words, the printed circuit board 11 and the interposer 12 cooperatively form a cap mounted on the printed circuit board 13, and the charging element 15 is mounted on the printed circuit board 13 and covered by the cap formed by the printed circuit board 11 and the interposer 12.

In some embodiments of the present disclosure, the charging element 15 includes an electromagnet. In some embodiments of the present disclosure, the charging element 15 includes a coil unit. Referring to FIGS. 1A and 1B, the electromagnet may have a ring-shaped body with coils. Further, the ring-shaped body of the charging element 15 may have a gap 150. That is, the charging element 15 includes a breach.

As shown in FIGS. 1A and 1B, the printed circuit board 11 has a surface 113 (e.g., an upper surface). In some embodiments of the present disclosure, an electronic component 18 may be mounted or disposed on the surface 113 of the printed circuit board 11 In some embodiments of the present disclosure, the electronic component 18 is an IR sensor.

As shown in FIGS. 1A and 1B, the printed circuit board 11 may have an opening 110. The opening 110 may substantially align with the gap 150 of the charging element 15 and be in communicate with the inner space 100. That is, the opening 110 may provide a passage extending from outside of the electronic device 1 into the inside of the electronic device 1. In some embodiments of the present disclosure, the electronic component 18 mounted on the surface of the substrate 11 is adjacent to the opening 110.

In other words, the interposer 12 defines an opening to accommodate the charging element 15.

That is, an external device could be put into the electronic device 1 and received at the gap 150 of the charging element 15 through the opening 110. When the external device is put into the electronic device 1 and received at the gap 150 of the charging element 15, the charging element 15 is driven to generate the electromagnetic field so that the external device is electrically coupled to the charging element 15 and charged by the electronic device 1. Since the electromagnetic field generated by the charging element is strongest at the gap 150 of the charging element 15, the external device is positioned at the gap when the external device is put into the electronic device 1 and charged by the charging element 15.

In some embodiments of the present disclosure, a plurality of electrical connections 128 is arranged between the printed circuit board 11 and the interposer 12, and a plurality of electrical connections 129 is arranged between the printed circuit board 13 and the interposer 12.

In some embodiments of the present disclosure, the printed circuit board 11, the interposer 12, the printed circuit board 13 and the charging element 15 are formed a manufacturing process of a printed circuit board. In some embodiments of the present disclosure, the printed circuit board 11, the interposer 12, the printed circuit board 13 and the charging element 15 are formed to be a portion of a printed circuit board.

FIG. 1C illustrates a schematic cross-sectional view along line A-A in FIG. 1B. As shown in FIG. 1C, the electronic device 1 may include the printed circuit board 11, the interposer 12, the printed circuit board 13 and the charging element 15 received within the space 100 defined by the printed circuit board 11, the interposer 12, the printed circuit board 13. The printed circuit board 11 may include conductive layers 111 and 113 and the dielectric layer 114. In some embodiments of the present disclosure, the conductive layer 111, 113 includes a circuit layer. In some embodiments of the present disclosure, the conductive layer 111, 113 includes a metal layer. In some embodiments of the present disclosure, the conductive layer 111, 113 includes a Cu layer. In some embodiments, the dielectric layer 114 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like.

As shown in FIG. 1C, the conductive layer 111 is arranged above the conductive layer 113. That is, the conductive layer 113 covers the charging element 15 and the conductive layer 111 covers the conductive layer 113 and the charging element 111. The conductive layer 113 may include a plurality of separated portions 1131 and 1132. The portions 1131 and 1132 are separated from each other. Referring to FIG. 1C, the portions 1131 and 1132 are spaced apart from each other and a gap 1130 is formed between the portions 1131 and 1132. Further, the conductive layer 111 may cover the gap 1130 between the portions 1131 and 1132 of the conductive layer 113.

As stated above, when the external device is put into the electronic device 1 and located at the gap 150 of the charging element 15, the charging element 15 is driven to generate the electromagnetic field so that the external device is electrically coupled to the charging element 15 and charged by the electronic device 1. The conductive layers 111 and 113 form an EMI shielding layer which is configured to shield an outside from the electromagnetic field produced by the charging element 15. Meanwhile, since the conductive layer 113 includes multiple separated portions 1131 and 1132, the eddy current generated from an electromagnetic induction effect caused by an electromagnetic field of the charging element 15 and the conductive layer(s) 111 and/or 113 is divided into multiple small size eddy currents which could not be gathered. Thus, negative effects caused by the eddy current may be reduced. The inductance and quality factor of the charging element 15 may be increased and the charge efficiency of the electronic device 1 may be improved. In addition, since the conductive layer 111 may cover the gap 1130 between the portions 1131 and 1132 of the conductive layer 113, the conductive layer 111 may block a stray magnetic field passing through the gap 1130.

Moreover, the printed circuit board 11 may include a barrier layer 112. The barrier layer 112 may include a magnetic permeable material. In some embodiments of the present disclosure, the barrier layer 112 includes a conductive material. In some embodiments of the present disclosure, the barrier layer 112 includes a non-conducting material. In some embodiments of the present disclosure, the barrier layer 112 abuts the conductive layer 113. That is, the barrier layer 112 may be embedded in the printed circuit board 11 and covered by the dielectric layer 114. In some embodiments of the present disclosure, the barrier layer 112 is disposed on a surface 116 (e.g., a lower surface) of the printed circuit board 11. That is, the barrier layer 112 may cover the dielectric layer 114 of the printed circuit board 11. Given the above, the barrier layer 112 is arranged between the charging element 15 and the conductive layers 111, 113. The barrier layer 112 may have a substantially circular area. The peripheral of the circular area of the barrier layer 112 may substantially conform to the outer edge of the ring-shaped charging element 15. That is, the barrier layer 112 may fully cover the charging element 15 and an area surrounded by the charging element 15. Thus, in a top view perspective, the barrier layer 112 may overlap the charging element 15. As stated above, the ring-shaped body of the charging element 15 may have the gap 150, and thus the circular area of the barrier layer 112 may have a blank corresponding to the gap 150.

As stated above, when the external device is put into the electronic device 1 and located at the gap 150 of the charging element 15, the charging element 15 is driven to generate the electromagnetic field so that the external device is electrically coupled to the charging element 15 and charged by the electronic device 1. The magnetic field lines generated from the charging element 15 may reach the barrier layer 112 before reaching the conductive layer 113 since a distance between the charging element 15 and the barrier layer 112 is shorter than a distance between the charging element 15 and the conductive layer 113. Therefore, the barrier layer 112 is configured to collect the magnetic field lines generated from the charging element 15 and thus block the electromagnetic induction effect caused by the electromagnetic field provided from the charging element 15 and the conductive layer 113. Further, the eddy current generated from the electromagnetic induction effect may be reduced. The inductance and quality factor of the charging element 15 may be increased and the charge efficiency of the electronic device 1 may be improved.

The printed circuit board 13 may include a conductive layer 131 and a dielectric layer 134. In some embodiments of the present disclosure, the conductive layer 131 includes a circuit layer. In some embodiments of the present disclosure, the conductive layer 131 includes a metal layer. In some embodiments of the present disclosure, the conductive layer 131 includes a Cu layer. In some embodiments of the present disclosure, the conductive layer 131 includes a ground layer. In some embodiments, the dielectric layer 134 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like.

Moreover, the printed circuit board 13 may include a barrier layer 132. The barrier layer 132 may include a magnetic permeable material. In some embodiments of the present disclosure, the barrier layer 132 includes a conductive material. In some embodiments of the present disclosure, the barrier layer 132 includes a non-conducting material. In some embodiments of the present disclosure, the barrier layer 132 abuts the conductive layer 131. That is, the barrier layer 132 may be embedded in the printed circuit board 13 and covered by the dielectric layer 134. In some embodiments of the present disclosure, the barrier layer 132 is disposed on a surface 135 (e.g., an upper surface) of the printed circuit board 13. That is, the barrier layer 132 may cover the dielectric layer 134 of the printed circuit board 13. Given the above, the barrier layer 132 is arranged between the charging element 15 and the conductive layer 131. The barrier layer 132 may have a substantially circular area. The peripheral of the circular area of the barrier layer 132 may substantially conform to the outer edge of the ring-shaped charging element 15. That is, the barrier layer 132 may fully cover the charging element 15 and an area surrounded by the charging element 15. Thus, in a bottom view perspective, the barrier layer 132 may overlap the charging element 15. As stated above, the ring-shaped body of the charging element 15 may have the gap 150, and thus the circular area of the barrier layer 132 may have a blank corresponding to the gap 150.

As stated above, when the external device is put into the electronic device 1 and located at the gap 150 of the charging element 15, the charging element 15 is driven to generate the electromagnetic field so that the external device is electrically coupled to the charging element 15 and charged by the electronic device 1. The conductive layer 131 forms an EMI shielding layer which is configured to shield an outside from the electromagnetic field produced by the charging element 15. The magnetic field lines generated from the charging element 15 may reach the barrier layer 132 before reaching the conductive layer 131 since a distance between the charging element 15 and the barrier layer 132 is shorter than a distance between the charging element 15 and the conductive layer 131. Therefore, the barrier layer 132 is configured to collect the magnetic field lines generated from the charging element 15 and thus block the electromagnetic induction effect caused by the electromagnetic field provided from the charging element 15 and the conductive layer 131. Further, the eddy current generated from the electromagnetic induction effect may be reduced. The inductance and quality factor of the charging element 15 may be increased and the charge efficiency of the electronic device 1 may be improved.

Referring to FIG. 1C, the charging element 15 may be arranged between the printed circuit board 11 with the conductive layers 111 and 113 and the printed circuit board 13 with the conductive layer 131. That is, the conductive layers 111 and 113 may be above the charging element 15 and the conductive layer 131 may be underneath the charging element 15. Thus, the conductive layers 111 and 113 and the conductive layer 131 are configured to accommodate loops of the electromagnetic field generated by the charging element 15.

The interposer 12 is disposed or mounted on the surface 135 of the printed circuit board 13, and is configured to support the printed circuit board 11. The interposer 12 may include an interconnection structure 121 and the dielectric layer 124. In some embodiments, the dielectric layer 124 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like. In some embodiments of the present disclosure, a plurality of electrical connections 129 is arranged between the surface 135 of the printed circuit board 13 and the interposer 12 so as to electrically connect printed circuit board 13 to the interposer 12. The electrical connection 129 may include a solder ball or a solder bump such as a C4 bump. In some embodiments of the present disclosure, a plurality of electrical connections 128 is arranged between the surface 116 of the printed circuit board 11 and the interposer 12 so as to electrically connect printed circuit board 11 to the interposer 12. The electrical connection 128 may include a solder ball or a solder bump such as a C4 bump. In some embodiments of the present disclosure, the interconnection structure 121 forms an EMI shielding layer. In some embodiments of the present disclosure, the electrical connection 128 and/or the electrical connection 129 may be a part of the EMI shielding layer. In other words, the conductive layers 111, 113, 131, the interconnection structure 121 and the electrical connection 128 and/or the electrical connection 129 are collectively configured to block the electromagnetic field.

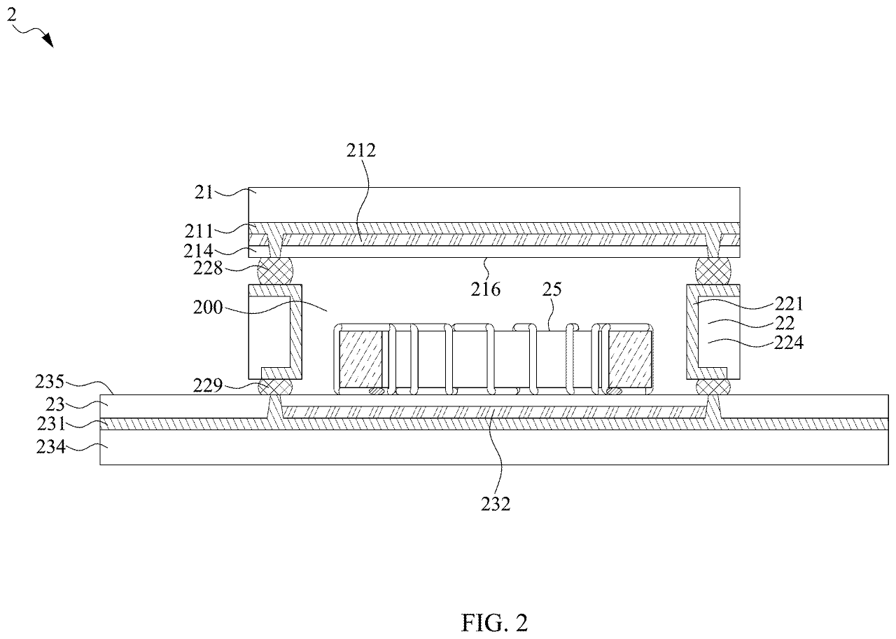

FIG. 2 is a schematic cross-sectional view of an electronic device 2 in accordance with an embodiment of the instant disclosure. The electronic device 2 may include a printed circuit board 21 (e.g., an upper circuit board), an interposer 22, a printed circuit board 23 (e.g., a lower circuit board) and a charging element 25. The interposer 22 is stacked on the printed circuit board 23 and the printed circuit board 21 is stacked on the interposer 22. That is, the interposer 22 is disposed on the printed circuit board 23 and supports the printed circuit board 21. As the interposer 22 is stacked on the printed circuit board 23 and the printed circuit board 21 is stacked on the interposer 22, the printed circuit board 21, the interposer 22 and the printed circuit board 23 may define an inner space 200. Further, the charging element 25 may be arranged within the inner space 200 defined by the printed circuit board 21, the interposer 22 and the printed circuit board 23. In some embodiments of the present disclosure, the space 200 may include a package body surrounding the charging element 25. Referring to FIG. 2, an area of the printed circuit board 23 may be larger than an area of the printed circuit board 21. In other words, the printed circuit board 21 and the interposer 22 cooperatively form a cap mounted on the printed circuit board 23, and the charging element 25 is mounted on the printed circuit board 23 and covered by the cap formed by the printed circuit board 21 and the interposer 22. In other words, the interposer 22 defines an opening to accommodate the charging element 25.

In some embodiments of the present disclosure, the charging element 25 is the same as or similar to the charging element 15. That is, the charging element 25 may include an electromagnet and have a ring-shaped body with coils. Further, the ring-shaped body of the charging element 25 may have a gap.

Meanwhile, the printed circuit board 21 may have an opening substantially aligning with the gap of the charging element 25 and be in communicate with the inner space 200. That is, the opening of the printed circuit board 21 may provide a passage extending from outside of the electronic device 2 into the inside of the electronic device 2. That is, an external device could be put into the electronic device 2 and located at the gap of the charging element 25. When the external device is put into the electronic device 2 and located at the gap of the charging element 25, the charging element 25 is driven to generate the electromagnetic field so that the external device is electrically coupled to the charging element 25 and charged by the electronic device 2.

Referring to FIG. 2, the printed circuit board 21 may include a conductive layer 211 and a dielectric layer 214. In some embodiments of the present disclosure, the conductive layer 211 includes a circuit layer. In some embodiments of the present disclosure, the conductive layer 211 includes a metal layer. In some embodiments of the present disclosure, the conductive layer 211 includes a Cu layer. In some embodiments, the dielectric layer 214 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like.

Moreover, the printed circuit board 21 may include a barrier layer 212. The barrier layer 212 may include a magnetic permeable material. In some embodiments of the present disclosure, the barrier layer 212 includes a conductive material. In some embodiments of the present disclosure, the barrier layer 212 includes a non-conducting material. In some embodiments of the present disclosure, the barrier layer 212 abuts the conductive layer 211. That is, the barrier layer 212 may be embedded in the printed circuit board 21 and covered by the dielectric layer 214. In some embodiments of the present disclosure, the barrier layer 212 is disposed on a surface 216 (e.g., a lower surface) of the printed circuit board 21. That is, the barrier layer 212 may cover the dielectric layer 214 of the printed circuit board 21. Given the above, the barrier layer 212 is arranged between the charging element 25 and the conductive layer 211. The barrier layer 212 may have a substantially circular area. The peripheral of the circular area of the barrier layer 212 may substantially conform to the outer edge of the ring-shaped charging element 25. That is, the barrier layer 212 may fully cover the charging element 25 and an area surrounded by the charging element 25. Thus, in a top view perspective, the barrier layer 212 may overlap the charging element 25. As stated above, the ring-shaped body of the charging element 25 may have the gap, and thus the circular area of the barrier layer 212 may have a blank corresponding to the gap of the charging element 25.

As stated above, when the external device is put into the electronic device 2 and located at the gap of the charging element 25, the charging element 25 is driven to generate the electromagnetic field so that the external device is electrically coupled to the charging element 25 and charged by the electronic device 2. The conductive layer 211 forms an EMI shielding layer which is configured to shield an outside from the electromagnetic field produced by the charging element 25. The magnetic field lines generated from the charging element 25 may reach the barrier layer 212 before reaching the conductive layer 211 since a distance between the charging element 25 and the barrier layer 212 is shorter than a distance between the charging element 25 and the conductive layer 211. Therefore, the barrier layer 212 is configured to collect the magnetic field lines generated from the charging element 25 and thus block the electromagnetic induction effect caused by the electromagnetic field provided from the charging element 25 and the conductive layer 211. Further, the eddy current generated from the electromagnetic induction effect may be reduced. The inductance and quality factor of the charging element 25 may be increased and the charge efficiency of the electronic device 2 may be improved.

The printed circuit board 23 may include a conductive layer 231 and a dielectric layer 234. In some embodiments of the present disclosure, the conductive layer 231 includes a circuit layer. In some embodiments of the present disclosure, the conductive layer 231 includes a metal layer. In some embodiments of the present disclosure, the conductive layer 231 includes a Cu layer. In some embodiments of the present disclosure, the conductive layer 231 includes a ground layer. In some embodiments, the dielectric layer 234 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like.

Moreover, the printed circuit board 23 may include a barrier layer 232. The barrier layer 232 may include a magnetic permeable material. In some embodiments of the present disclosure, the barrier layer 232 includes a conductive material. In some embodiments of the present disclosure, the barrier layer 232 includes a non-conducting material. In some embodiments of the present disclosure, the barrier layer 232 abuts the conductive layer 231. That is, the barrier layer 232 may be embedded in the printed circuit board 23 and covered by the dielectric layer 234. In some embodiments of the present disclosure, the barrier layer 232 is disposed on a surface 235 (e.g., an upper surface) of the printed circuit board 23. That is, the barrier layer 232 may cover the dielectric layer 234 of the printed circuit board 23. Given the above, the barrier layer 232 is arranged between the charging element 25 and the conductive layer 231. The barrier layer 232 may have a substantially circular area. The peripheral of the circular area of the barrier layer 232 may substantially conform to the outer edge of the ring-shaped charging element 25. That is, the barrier layer 232 may fully cover the charging element 25 and an area surrounded by the charging element 25. Thus, in a bottom view perspective, the barrier layer 232 may overlap the charging element 25. As stated above, the ring-shaped body of the charging element 25 may have the gap, and thus the circular area of the barrier layer 232 may have a blank corresponding to the gap of the charging element 25.

As stated above, when the external device is put into the electronic device 2 and located at the gap of the charging element 25, the charging element 25 is driven to generate the electromagnetic field so that the external device is electrically coupled to the charging element 25 and charged by the electronic device 2. The conductive layer 231 forms an EMI shielding layer which is configured to shield an outside from the electromagnetic field produced by the charging element 25. The magnetic field lines generated from the charging element 25 may reach the barrier layer 232 before reaching the conductive layer 231 since a distance between the charging element 25 and the barrier layer 232 is shorter than a distance between the charging element 25 and the conductive layer 231. Therefore, the barrier layer 232 is configured to collect the magnetic field lines generated from the charging element 25 and thus block the electromagnetic induction effect caused by the electromagnetic field provided from the charging element 25 and the conductive layer 231. Further, the eddy current generated from the electromagnetic induction effect may be reduced. The inductance and quality factor of the charging element 25 may be increased and the charge efficiency of the electronic device 2 may be improved.

Referring to FIG. 2, the charging element 25 may be arranged between the printed circuit board 21 with the conductive layer 211 and the printed circuit board 23 with the conductive layer 231. That is, the conductive layer 211 may be above the charging element 25 and the conductive layer 231 may be underneath the charging element 25. Thus, the conductive layer 211 and the conductive layer 231 are configured to accommodate loops of the electromagnetic field generated by the charging element 25.

The interposer 22 is disposed or mounted on the surface 235 of the printed circuit board 23, and is configured to support the printed circuit board 21. The interposer 22 may include an interconnection structure 221 and the dielectric layer 224. In some embodiments, the dielectric layer 224 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like. In some embodiments of the present disclosure, a plurality of electrical connections 229 is arranged between the surface 235 of the printed circuit board 23 and the interposer 22 so as to electrically connect printed circuit board 23 to the interposer 22. The electrical connection 229 may include a solder ball or a solder bump such as a C4 bump. In some embodiments of the present disclosure, a plurality of electrical connections 228 is arranged between the surface 216 of the printed circuit board 21 and the interposer 22 so as to electrically connect printed circuit board 21 to the interposer 22. The electrical connection 228 may include a solder ball or a solder bump such as a C4 bump. In some embodiments of the present disclosure, the interconnection structure 221 forms an EMI shielding layer. In some embodiments of the present disclosure, the electrical connection 228 and/or the electrical connection 229 may be a part of the EMI shielding layer. In other words, the conductive layers 211, 231, the interconnection structure 221 and the electrical connection 228 and/or the electrical connection 229 are collectively configured to block the electromagnetic field.

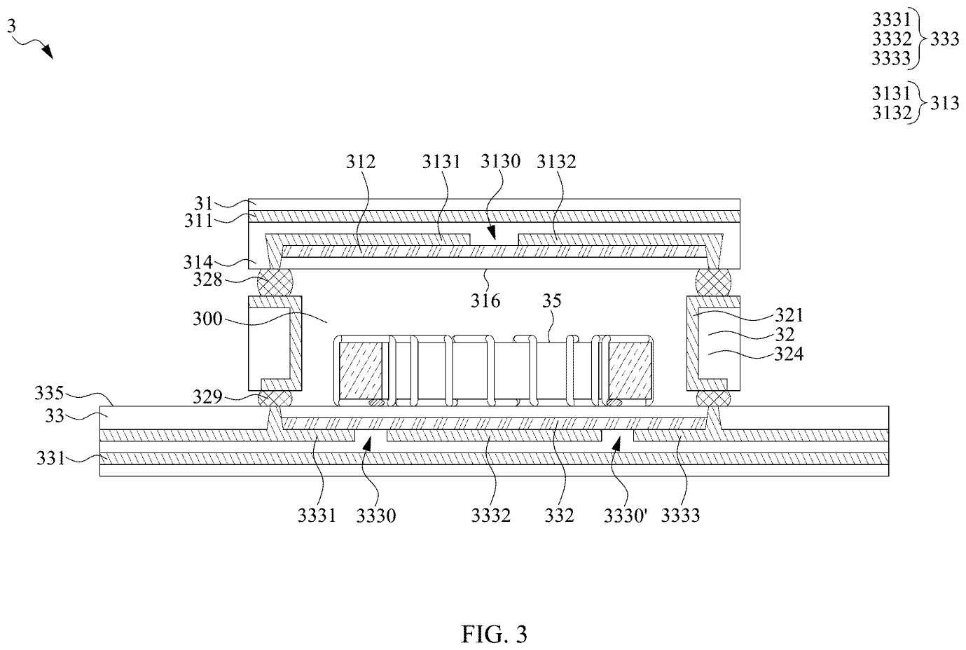

FIG. 3 is a schematic cross-sectional view of an electronic device 3 in accordance with an embodiment of the instant disclosure. The electronic device 3 may include a printed circuit board 31 (e.g., an upper circuit board), an interposer 32, a printed circuit board 33 (e.g., a lower circuit board) and a charging element 35. The interposer 32 is stacked on the printed circuit board 33 and the printed circuit board 31 is stacked on the interposer 32. That is, the interposer 32 is disposed on the printed circuit board 33 and supports the printed circuit board 31. As the interposer 32 is stacked on the printed circuit board 33 and the printed circuit board 31 is stacked on the interposer 32, the printed circuit board 31, the interposer 32 and the printed circuit board 33 may define an inner space 300. Further, the charging element 35 may be arranged within the inner space 300 defined by the printed circuit board 31, the interposer 32 and the printed circuit board 33. In some embodiments of the present disclosure, the space 300 may include a package body surrounding the charging element 35. Referring to FIG. 3, an area of the printed circuit board 33 may be larger than an area of the printed circuit board 31. In other words, the printed circuit board 31 and the interposer 322 cooperatively form a cap mounted on the printed circuit board 33, and the charging element 35 is mounted on the printed circuit board 33 and covered by the cap formed by the printed circuit board 31 and the interposer 32. In other words, the interposer 32 defines an opening to accommodate the charging element 35.

In some embodiments of the present disclosure, the charging element 35 is the same as or similar to the charging element 15. That is, the charging element 35 may include an electromagnet and have a ring-shaped body with coils. Further, the ring-shaped body of the charging element 35 may have a gap.

Meanwhile, the printed circuit board 31 may have an opening substantially aligning with the gap of the charging element 35 and be in communicate with the inner space 300. That is, the opening of the printed circuit board 31 may provide a passage extending from outside of the electronic device 3 into the inside of the electronic device 3. That is, an external device could be put into the electronic device 3 and located at the gap of the charging element 35. When the external device is put into the electronic device 3 and located at the gap of the charging element 35, the charging element 35 is driven to generate the electromagnetic field so that the external device is electrically coupled to the charging element 35 and charged by the electronic device 3.

The printed circuit board 31 may include conductive layers 311 and 313 and the dielectric layer 314. In some embodiments of the present disclosure, the conductive layer 311, 313 includes a circuit layer. In some embodiments of the present disclosure, the conductive layer 311, 313 includes a metal layer. In some embodiments of the present disclosure, the conductive layer 311, 313 includes a Cu layer. In some embodiments, the dielectric layer 314 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like.

As shown in FIG. 3, the conductive layer 311 is arranged above the conductive layer 313. That is, the conductive layer 313 covers the charging element 35 and the conductive layer 311 covers the conductive layer 313 and the charging element 311. The conductive layer 313 may include a plurality of separated portions 3131 and 3132. The portions 3131 and 3132 are separated from each other. Referring to FIG. 3, the portions 3131 and 3132 are spaced apart from each other and a gap 3130 is formed between the portions 3131 and 3132. Further, the conductive layer 311 may cover the gap 3130 between the portions 3131 and 3132 of the conductive layer 313.

As stated above, when the external device is put into the electronic device 3 and located at the gap of the charging element 35, the charging element 35 is driven to generate the electromagnetic field so that the external device is electrically coupled to the charging element 35 and charged by the electronic device 3. The conductive layers 311 and 313 form an EMI shielding layer which is configured to shield an outside from the electromagnetic field produced by the charging element 35. Meanwhile, since the conductive layer 313 includes multiple separated portions 3131 and 3132, the eddy current generated from an electromagnetic induction effect caused by an electromagnetic field of the charging element 35 and the conductive layer(s) 311 and/or 313 is divided into multiple small size eddy currents which could not be gathered. Thus, negative effects caused by the eddy current may be reduced. The inductance and quality factor of the charging element 35 may be increased and the charge efficiency of the electronic device 3 may be improved. In addition, since the conductive layer 311 may cover the gap 3130 between the portions 3131 and 3132 of the conductive layer 313, the conductive layer 311 may block a stray magnetic field passing through the gap 3130.

Moreover, the printed circuit board 31 may include a barrier layer 312. The barrier layer 312 may include a magnetic permeable material. In some embodiments of the present disclosure, the barrier layer 312 includes a conductive material. In some embodiments of the present disclosure, the barrier layer 312 includes a non-conducting material. In some embodiments of the present disclosure, the barrier layer 312 abuts the conductive layer 313. That is, the barrier layer 312 may be embedded in the printed circuit board 31 and covered by the dielectric layer 314. In some embodiments of the present disclosure, the barrier layer 312 is disposed on a surface 316 (e.g., a lower surface) of the printed circuit board 31. That is, the barrier layer 312 may cover the dielectric layer 314 of the printed circuit board 31. Given the above, the barrier layer 312 is arranged between the charging element 35 and the conductive layers 311, 313. The barrier layer 312 may have a substantially circular area. The peripheral of the circular area of the barrier layer 312 may substantially conform to the outer edge of the ring-shaped charging element 35. That is, the barrier layer 312 may fully cover the charging element 35 and an area surrounded by the charging element 35. Thus, in a top view perspective, the barrier layer 312 may overlap the charging element 35. As stated above, the ring-shaped body of the charging element 35 may have the gap, and thus the circular area of the barrier layer 312 may have a blank corresponding to the gap of the charging element 35.

As stated above, when the external device is put into the electronic device 3 and located at the gap of the charging element 35, the charging element 35 is driven to generate the electromagnetic field so that the external device is electrically coupled to the charging elemen3 15 and charged by the electronic device 3. The magnetic field lines generated from the charging element 35 may reach the barrier layer 312 before reaching the conductive layer 313 since a distance between the charging element 35 and the barrier layer 312 is shorter than a distance between the charging element 35 and the conductive layer 313. Therefore, the barrier layer 312 is configured to collect the magnetic field lines generated from the charging element 35 and thus block the electromagnetic induction effect caused by the electromagnetic field provided from the charging element 35 and the conductive layer 313. Further, the eddy current generated from the electromagnetic induction effect may be reduced. The inductance and quality factor of the charging element 35 may be increased and the charge efficiency of the electronic device 3 may be improved.

The printed circuit board 33 may include conductive layers 331 and 333 and the dielectric layer 334. In some embodiments of the present disclosure, the conductive layer 331, 333 includes a circuit layer. In some embodiments of the present disclosure, the conductive layer 331, 333 includes a metal layer. In some embodiments of the present disclosure, the conductive layer 331, 333 includes a Cu layer. In some embodiments of the present disclosure, the conductive layer 331 or 333 includes a ground layer. In some embodiments, the dielectric layer 334 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like.

As shown in FIG. 3, the conductive layer 331 is arranged underneath the conductive layer 333. The conductive layer 313 may include a plurality of separated portions 3331, 3332 and 333. The portions 3331 and 3332 are separated from each other. Referring to FIG. 3, the portions 3331 and 3332 are spaced apart from each other and a gap 3330 is formed between the portions 3331 and 3332. Further, in a bottom view perspective, the conductive layer 331 may cover the gap 3330 between the portions 3331 and 3332 of the conductive layer 333. Moreover, the portions 3332 and 3333 are separated from each other. Referring to FIG. 3, the portions 3332 and 3333 are spaced apart from each other and a gap 3330′ is formed between the portions 3332 and 3333. Further, in a bottom view perspective, the conductive layer 331 may cover the gap 3330′ between the portions 3332 and 3333 of the conductive layer 333.

As stated above, when the external device is put into the electronic device 3 and located at the gap of the charging element 35, the charging element 35 is driven to generate the electromagnetic field so that the external device is electrically coupled to the charging element 35 and charged by the electronic device 3. The conductive layers 331 and 333 form an EMI shielding layer which is configured to shield an outside from the electromagnetic field produced by the charging element 35. Meanwhile, since the conductive layer 333 includes multiple separated portions 3331, 3332 and 333, the eddy current generated from an electromagnetic induction effect caused by an electromagnetic field of the charging element 35 and the conductive layer(s) 331 and/or 333 is divided into multiple small size eddy currents which could not be gathered. Thus, negative effects caused by the eddy current may be reduced. The inductance and quality factor of the charging element 35 may be increased and the charge efficiency of the electronic device 3 may be improved. In addition, since the conductive layer 331 may cover the gaps 3330 between the portions 3331 and 3332 and the gap 3330′ between the portions 3332 and 3333, the conductive layer 331 may block a stray magnetic field passing through the gap 3330 and/or the gap 3330′.

Moreover, the printed circuit board 33 may include a barrier layer 332. The barrier layer 332 may include a magnetic permeable material. In some embodiments of the present disclosure, the barrier layer 332 includes a conductive material. In some embodiments of the present disclosure, the barrier layer 332 includes a non-conducting material. In some embodiments of the present disclosure, the barrier layer 332 abuts the conductive layer 333. That is, the barrier layer 312 may be embedded in the printed circuit board 33 and covered by the dielectric layer 334. In some embodiments of the present disclosure, the barrier layer 332 is disposed on a surface 335 (e.g., an upper surface) of the printed circuit board 33. That is, the barrier layer 332 may cover the dielectric layer 334 of the printed circuit board 33. Given the above, the barrier layer 332 is arranged between the charging element 35 and the conductive layers 331, 333. The barrier layer 332 may have a substantially circular area. The peripheral of the circular area of the barrier layer 332 may substantially conform to the outer edge of the ring-shaped charging element 35. That is, the barrier layer 332 may fully cover the charging element 35 and an area surrounded by the charging element 35. Thus, in the bottom view perspective, the barrier layer 332 may overlap the charging element 35. As stated above, the ring-shaped body of the charging element 35 may have the gap, and thus the circular area of the barrier layer 332 may have a blank corresponding to the gap of the charging element 35.

As stated above, when the external device is put into the electronic device 3 and located at the gap of the charging element 35, the charging element 35 is driven to generate the electromagnetic field so that the external device is electrically coupled to the charging elemen3 15 and charged by the electronic device 3. The magnetic field lines generated from the charging element 35 may reach the barrier layer 332 before reaching the conductive layer 333 since a distance between the charging element 35 and the barrier layer 332 is shorter than a distance between the charging element 35 and the conductive layer 333. Therefore, the barrier layer 332 is configured to collect the magnetic field lines generated from the charging element 35 and thus block the electromagnetic induction effect caused by the electromagnetic field provided from the charging element 35 and the conductive layer 333. Further, the eddy current generated from the electromagnetic induction effect may be reduced. The inductance and quality factor of the charging element 35 may be increased and the charge efficiency of the electronic device 3 may be improved.

Referring to FIG. 3, the charging element 35 may be arranged between the printed circuit board 31 with the conductive layers 311 and 313 and the printed circuit board 33 with the conductive layers 331 and 333. That is, the conductive layers 331 and 313 may be above the charging element 35 and the conductive layers 331 and 333 may be underneath the charging element 35. Thus, the conductive layers 311 and 313 and the conductive layers 331 and 333 are configured to accommodate loops of the electromagnetic field generated by the charging element 35.

The interposer 32 is disposed or mounted on the surface 335 of the printed circuit board 33, and is configured to support the printed circuit board 31. The interposer 32 may include an interconnection structure 321 and the dielectric layer 324. In some embodiments, the dielectric layer 324 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like. In some embodiments of the present disclosure, a plurality of electrical connections 329 is arranged between the surface 335 of the printed circuit board 33 and the interposer 32 so as to electrically connect printed circuit board 33 to the interposer 32. The electrical connection 329 may include a solder ball or a solder bump such as a C4 bump. In some embodiments of the present disclosure, a plurality of electrical connections 328 is arranged between the surface 316 of the printed circuit board 31 and the interposer 32 so as to electrically connect printed circuit board 31 to the interposer 32. The electrical connection 328 may include a solder ball or a solder bump such as a C4 bump. In some embodiments of the present disclosure, the interconnection structure 321 forms an EMI shielding layer. In some embodiments of the present disclosure, the electrical connection 328 and/or the electrical connection 329 may be a part of the EMI shielding layer. In other words, the conductive layers 311, 313, 331, 333 the interconnection structure 321 and the electrical connection 328 and/or the electrical connection 329 are collectively configured to block the electromagnetic field.

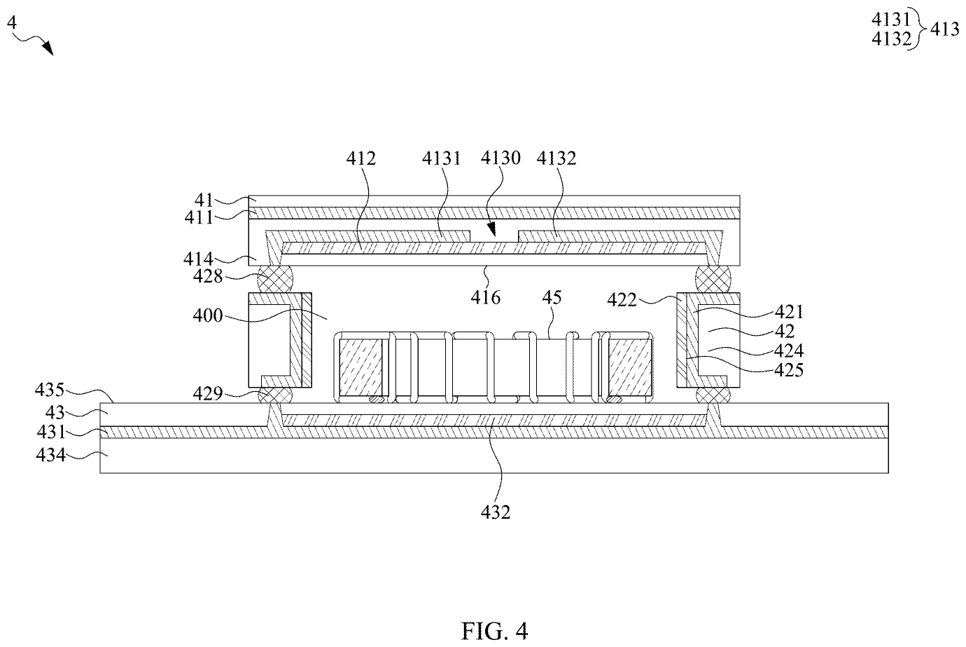

FIG. 4 is a schematic cross-sectional view of an electronic device 4 in accordance with an embodiment of the instant disclosure. The electronic device 4 may include a printed circuit board 41 (e.g., an upper circuit board), an interposer 42, a printed circuit board 43 (e.g., a lower circuit board) and a charging element 45. The interposer 42 is stacked on the printed circuit board 43 and the printed circuit board 41 is stacked on the interposer 42. That is, the interposer 42 is disposed on the printed circuit board 43 and supports the printed circuit board 41. As the interposer 42 is stacked on the printed circuit board 43 and the printed circuit board 41 is stacked on the interposer 42, the printed circuit board 41, the interposer 42 and the printed circuit board 43 may define an inner space 400. Further, the charging element 45 may be arranged within the inner space 400 defined by the printed circuit board 41, the interposer 42 and the printed circuit board 43. In some embodiments of the present disclosure, the space 400 may include a package body surrounding the charging element 45. Referring to FIG. 4, an area of the printed circuit board 43 may be larger than an area of the printed circuit board 41. In other words, the printed circuit board 41 and the interposer 422 cooperatively form a cap mounted on the printed circuit board 43, and the charging element 45 is mounted on the printed circuit board 43 and covered by the cap formed by the printed circuit board 41 and the interposer 42. In other words, the interposer 42 defines an opening to accommodate the charging element 45.

In some embodiments of the present disclosure, the charging element 45 is the same as or similar to the charging element 15. That is, the charging element 45 may include an electromagnet and have a ring-shaped body with coils. Further, the ring-shaped body of the charging element 45 may have a gap.

Meanwhile, the printed circuit board 41 may have an opening substantially aligning with the gap of the charging element 45 and be in communicate with the inner space 400. That is, the opening of the printed circuit board 41 may provide a passage extending from outside of the electronic device 4 into the inside of the electronic device 4. That is, an external device could be put into the electronic device 4 and located at the gap of the charging element 45. When the external device is put into the electronic device 4 and located at the gap of the charging element 45, the charging element 45 is driven to generate the electromagnetic field so that the external device is electrically coupled to the charging element 45 and charged by the electronic device 4.

The printed circuit board 41 may include conductive layers 411 and 413 and the dielectric layer 414. In some embodiments of the present disclosure, the conductive layer 411, 413 includes a circuit layer. In some embodiments of the present disclosure, the conductive layer 411, 413 includes a metal layer. In some embodiments of the present disclosure, the conductive layer 411, 413 includes a Cu layer. In some embodiments, the dielectric layer 414 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like.

As shown in FIG. 4, the conductive layer 411 is arranged above the conductive layer 413. That is, the conductive layer 413 covers the charging element 45 and the conductive layer 411 covers the conductive layer 413 and the charging element 411. The conductive layer 413 may include a plurality of separated portions 4131 and 4132. The portions 4131 and 4132 are separated from each other. Referring to FIG. 4, the portions 4131 and 4132 are spaced apart from each other and a gap 4130 is formed between the portions 4131 and 4132. Further, the conductive layer 411 may cover the gap 4130 between the portions 4131 and 4132 of the conductive layer 413.

As stated above, when the external device is put into the electronic device 4 and located at the gap of the charging element 45, the charging element 45 is driven to generate the electromagnetic field so that the external device is electrically coupled to the charging element 45 and charged by the electronic device 4. The conductive layers 411 and 413 form an EMI shielding layer which is configured to shield an outside from the electromagnetic field produced by the charging element 45. Meanwhile, since the conductive layer 413 includes multiple separated portions 4131 and 4132, the eddy current generated from an electromagnetic induction effect caused by an electromagnetic field of the charging element 45 and the conductive layer(s) 411 and/or 413 is divided into multiple small size eddy currents which could not be gathered. Thus, negative effects caused by the eddy current may be reduced. The inductance and quality factor of the charging element 45 may be increased and the charge efficiency of the electronic device 4 may be improved. In addition, since the conductive layer 411 may cover the gap 4130 between the portions 4131 and 4132 of the conductive layer 413, the conductive layer 411 may block a stray magnetic field passing through the gap 4130.

Moreover, the printed circuit board 41 may include a barrier layer 412. The barrier layer 412 may include a magnetic permeable material. In some embodiments of the present disclosure, the barrier layer 412 includes a conductive material. In some embodiments of the present disclosure, the barrier layer 412 includes a non-conducting material. In some embodiments of the present disclosure, the barrier layer 412 abuts the conductive layer 413. That is, the barrier layer 412 may be embedded in the printed circuit board 41 and covered by the dielectric layer 414. In some embodiments of the present disclosure, the barrier layer 412 is disposed on a surface 416 (e.g., a lower surface) of the printed circuit board 41. That is, the barrier layer 412 may cover the dielectric layer 414 of the printed circuit board 41. Given the above, the barrier layer 412 is arranged between the charging element 45 and the conductive layers 411, 413. The barrier layer 412 may have a substantially circular area. The peripheral of the circular area of the barrier layer 412 may substantially conform to the outer edge of the ring-shaped charging element 45. That is, the barrier layer 412 may fully cover the charging element 45 and an area surrounded by the charging element 45. Thus, in a top view perspective, the barrier layer 412 may overlap the charging element 45. As stated above, the ring-shaped body of the charging element 45 may have the gap, and thus the circular area of the barrier layer 412 may have a blank corresponding to the gap of the charging element 45.

As stated above, when the external device is put into the electronic device 4 and located at the gap of the charging element 45, the charging element 45 is driven to generate the electromagnetic field so that the external device is electrically coupled to the charging element 45 and charged by the electronic device 4. The magnetic field lines generated from the charging element 45 may reach the barrier layer 412 before reaching the conductive layer 413 since a distance between the charging element 45 and the barrier layer 412 is shorter than a distance between the charging element 45 and the conductive layer 413. Therefore, the barrier layer 412 is configured to collect the magnetic field lines generated from the charging element 45 and thus block the electromagnetic induction effect caused by the electromagnetic field provided from the charging element 45 and the conductive layer 413. Further, the eddy current generated from the electromagnetic induction effect may be reduced. The inductance and quality factor of the charging element 45 may be increased and the charge efficiency of the electronic device 4 may be improved.

The printed circuit board 43 may include a conductive layer 431 and a dielectric layer 434. In some embodiments of the present disclosure, the conductive layer 431 includes a circuit layer. In some embodiments of the present disclosure, the conductive layer 431 includes a metal layer. In some embodiments of the present disclosure, the conductive layer 431 includes a Cu layer. In some embodiments of the present disclosure, the conductive layer 431 includes a ground layer. In some embodiments, the dielectric layer 434 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like.

Moreover, the printed circuit board 43 may include a barrier layer 432. The barrier layer 432 may include a magnetic permeable material. In some embodiments of the present disclosure, the barrier layer 432 includes a conductive material. In some embodiments of the present disclosure, the barrier layer 432 includes a non-conducting material. In some embodiments of the present disclosure, the barrier layer 432 abuts the conductive layer 431. That is, the barrier layer 432 may be embedded in the printed circuit board 43 and covered by the dielectric layer 434. In some embodiments of the present disclosure, the barrier layer 432 is disposed on a surface 435 (e.g., an upper surface) of the printed circuit board 43. That is, the barrier layer 432 may cover the dielectric layer 434 of the printed circuit board 43. Given the above, the barrier layer 432 is arranged between the charging element 45 and the conductive layer 431. The barrier layer 432 may have a substantially circular area. The peripheral of the circular area of the barrier layer 432 may substantially conform to the outer edge of the ring-shaped charging element 45. That is, the barrier layer 432 may fully cover the charging element 45 and an area surrounded by the charging element 45. Thus, in a bottom view perspective, the barrier layer 432 may overlap the charging element 45. As stated above, the ring-shaped body of the charging element 45 may have the gap, and thus the circular area of the barrier layer 432 may have a blank corresponding to the gap of the charging element 45.

As stated above, when the external device is put into the electronic device 4 and located at the gap of the charging element 45, the charging element 45 is driven to generate the electromagnetic field so that the external device is electrically coupled to the charging element 45 and charged by the electronic device 4. The conductive layer 431 forms an EMI shielding layer which is configured to shield an outside from the electromagnetic field produced by the charging element 45. The magnetic field lines generated from the charging element 45 may reach the barrier layer 432 before reaching the conductive layer 431 since a distance between the charging element 45 and the barrier layer 432 is shorter than a distance between the charging element 45 and the conductive layer 431. Therefore, the barrier layer 432 is configured to collect the magnetic field lines generated from the charging element 45 and thus block the electromagnetic induction effect caused by the electromagnetic field provided from the charging element 45 and the conductive layer 431. Further, the eddy current generated from the electromagnetic induction effect may be reduced. The inductance and quality factor of the charging element 45 may be increased and the charge efficiency of the electronic device 4 may be improved.

Referring to FIG. 4, the charging element 45 may be arranged between the printed circuit board 41 with the conductive layers 411 and 413 and the printed circuit board 43 with the conductive layer 431. That is, the conductive layers 411 and 413 may be above the charging element 45 and the conductive layer 431 may be underneath the charging element 45. Thus, the conductive layers 411 and 413 and the conductive layer 431 are configured to accommodate loops of the electromagnetic field generated by the charging element 45.

The interposer 42 is disposed or mounted on the surface 435 of the printed circuit board 43, and is configured to support the printed circuit board 41. The interposer 42 may include an interconnection structure 421 and the dielectric layer 424. In some embodiments, the dielectric layer 424 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like. In some embodiments of the present disclosure, a plurality of electrical connections 429 is arranged between the surface 435 of the printed circuit board 43 and the interposer 42 so as to electrically connect printed circuit board 43 to the interposer 42. The electrical connection 429 may include a solder ball or a solder bump such as a C4 bump. In some embodiments of the present disclosure, a plurality of electrical connections 428 is arranged between the surface 416 of the printed circuit board 41 and the interposer 42 so as to electrically connect printed circuit board 41 to the interposer 42. The electrical connection 428 may include a solder ball or a solder bump such as a C4 bump. In some embodiments of the present disclosure, the interconnection structure 421 forms an EMI shielding layer. In some embodiments of the present disclosure, the electrical connection 428 and/or the electrical connection 429 may be a part of the EMI shielding layer. In other words, the conductive layers 411, 413, 431, the interconnection structure 421 and the electrical connection 428 and/or the electrical connection 429 are collectively configured to block the electromagnetic field.

In addition, the interposer 42 may include a barrier layer 422. The barrier layer 422 may include a magnetic permeable material. In some embodiments of the present disclosure, the barrier layer 422 includes a conductive material. In some embodiments of the present disclosure, the barrier layer 422 includes a non-conducting material. In some embodiments of the present disclosure, the barrier layer 422 abuts the interconnection structure 421. That is, the barrier layer 422 may be embedded in the interposer 42 and covered by the dielectric layer 424. In some embodiments of the present disclosure, the barrier layer 422 is disposed on a surface 425 (e.g., an inner surface) of the interposer 42. That is, the barrier layer 422 may cover the dielectric layer 424 of the interposer 42. Given the above, the barrier layer 422 is arranged between the charging element 45 and the interconnection structure 421.

As stated above, when the external device is put into the electronic device 4 and located at the gap of the charging element 45, the charging element 45 is driven to generate the electromagnetic field so that the external device is electrically coupled to the charging element 45 and charged by the electronic device 4. The interconnection structure 421 forms an EMI shielding layer which is configured to shield an outside from the electromagnetic field produced by the charging element 45. The magnetic field lines generated from the charging element 45 may reach the barrier layer 422 before reaching the interconnection structure 421 since a distance between the charging element 45 and the barrier layer 422 is shorter than a distance between the charging element 45 and the interconnection structure 421. Therefore, the barrier layer 422 is configured to collect the magnetic field lines generated from the charging element 45 and thus block the electromagnetic induction effect caused by the electromagnetic field provided from the charging element 45 and the interconnection structure 421. Further, the eddy current generated from the electromagnetic induction effect may be reduced. The inductance and quality factor of the charging element 45 may be increased and the charge efficiency of the electronic device 4 may be improved.

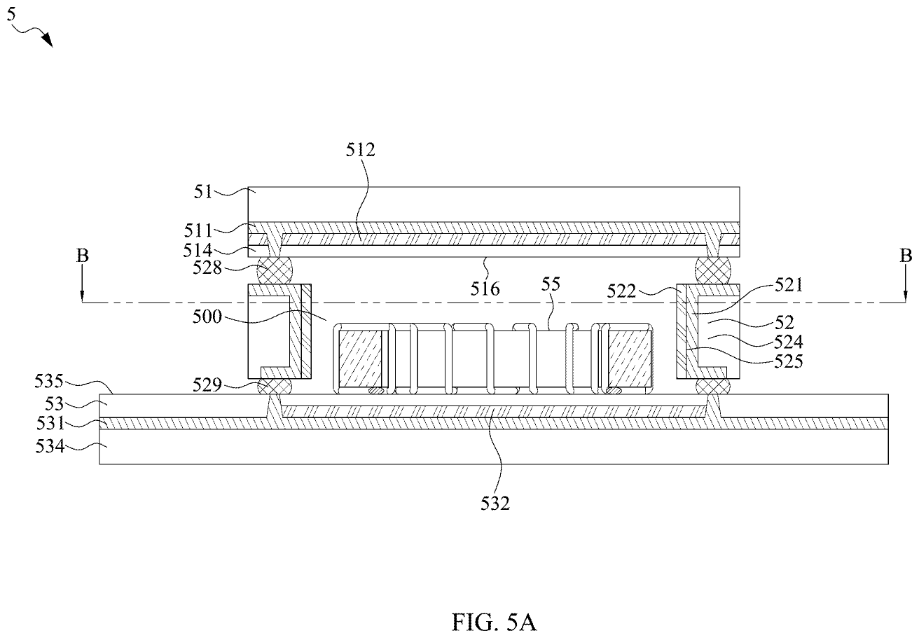

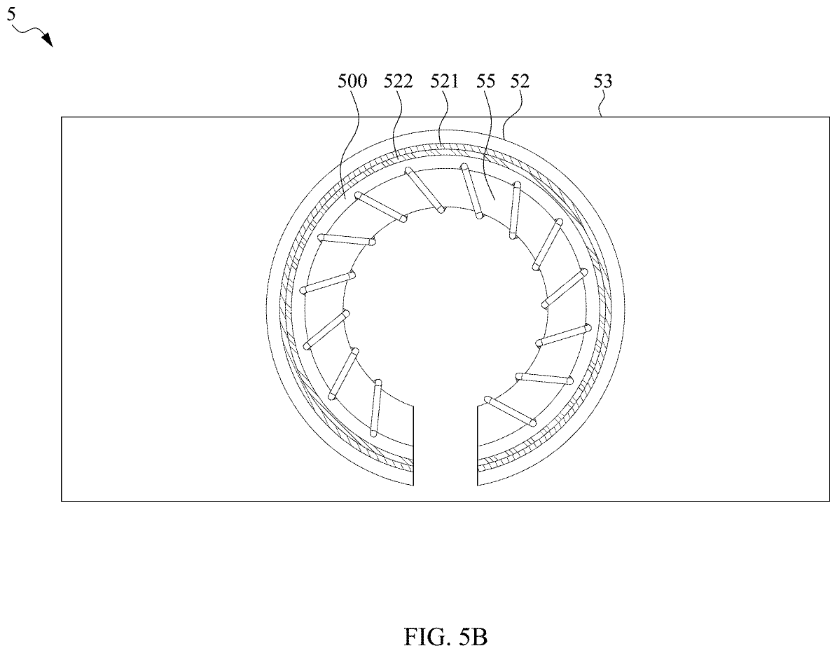

FIG. 5A is a schematic cross-sectional view of an electronic device 5 in accordance with an embodiment of the instant disclosure. The electronic device 5 may include a printed circuit board 51 (e.g., an upper circuit board), an interposer 52, a printed circuit board 53 (e.g., a lower circuit board) and a charging element 55. The interposer 52 is stacked on the printed circuit board 53 and the printed circuit board 51 is stacked on the interposer 52. That is, the interposer 52 is disposed on the printed circuit board 53 and supports the printed circuit board 51. When the interposer 52 is stacked on the printed circuit board 53 and the printed circuit board 51 is stacked on the interposer 52, the printed circuit board 51, the interposer 52 and the printed circuit board 53 may define an inner space 500. Further, the charging element 55 may be arranged within the inner space 500 defined by the printed circuit board 51, the interposer 52 and the printed circuit board 53. In some embodiments of the present disclosure, the space 500 may include a package body surrounding the charging element 55. Referring to FIG. 5A, an area of the printed circuit board 53 may be larger than an area of the printed circuit board 51. In other words, the printed circuit board 51 and the interposer 52 cooperatively form a cap mounted on the printed circuit board 53, and the charging element 55 is mounted on the printed circuit board 53 and covered by the cap formed by the printed circuit board 51 and the interposer 52. In other words, the interposer 52 defines an opening to accommodate the charging element 55.

In some embodiments of the present disclosure, the charging element 55 is the same as or similar to the charging element 15. That is, the charging element 55 may include an electromagnet and have a ring-shaped body with coils. Further, the ring-shaped body of the charging element 55 may have a gap.

Meanwhile, the printed circuit board 51 may have an opening substantially aligning with the gap of the charging element 55 and be in communicate with the inner space 500. That is, the opening of the printed circuit board 51 may provide a passage extending from outside of the electronic device 5 into the inside of the electronic device 5. That is, an external device could be put into the electronic device 5 and located at the gap of the charging element 55. When the external device is put into the electronic device 5 and located at the gap of the charging element 55, the charging element 55 is driven to generate the electromagnetic field so that the external device is electrically coupled to the charging element 55 and charged by the electronic device 5.

Referring to FIG. 5A, the printed circuit board 51 may include a conductive layer 511 and a dielectric layer 514. In some embodiments of the present disclosure, the conductive layer 511 includes a circuit layer. In some embodiments of the present disclosure, the conductive layer 511 includes a metal layer. In some embodiments of the present disclosure, the conductive layer 511 includes a Cu layer. In some embodiments, the dielectric layer 514 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like.

Moreover, the printed circuit board 51 may include a barrier layer 512. The barrier layer 512 may include a magnetic permeable material. In some embodiments of the present disclosure, the barrier layer 512 includes a conductive material. In some embodiments of the present disclosure, the barrier layer 512 includes a non-conducting material. In some embodiments of the present disclosure, the barrier layer 512 abuts the conductive layer 511. That is, the barrier layer 512 may be embedded in the printed circuit board 51 and covered by the dielectric layer 514. In some embodiments of the present disclosure, the barrier layer 512 is disposed on a surface 516 (e.g., a lower surface) of the printed circuit board 51. That is, the barrier layer 512 may cover the dielectric layer 514 of the printed circuit board 51. Given the above, the barrier layer 512 is arranged between the charging element 55 and the conductive layer 511. The barrier layer 512 may have a substantially circular area. The peripheral of the circular area of the barrier layer 512 may substantially conform to the outer edge of the ring-shaped charging element 55. That is, the barrier layer 512 may fully cover the charging element 55 and an area surrounded by the charging element 55. Thus, in a top view perspective, the barrier layer 512 may overlap the charging element 55. As stated above, the ring-shaped body of the charging element 55 may have the gap, and thus the circular area of the barrier layer 512 may have a blank corresponding to the gap of the charging element 55.

As stated above, when the external device is put into the electronic device 5 and located at the gap of the charging element 55, the charging element 55 is driven to generate the electromagnetic field so that the external device is electrically coupled to the charging element 55 and charged by the electronic device 5. The conductive layer 511 forms an EMI shielding layer which is configured to shield an outside from the electromagnetic field produced by the charging element 55. The magnetic field lines generated from the charging element 55 may reach the barrier layer 512 before reaching the conductive layer 511 since a distance between the charging element 55 and the barrier layer 512 is shorter than a distance between the charging element 55 and the conductive layer 511. Therefore, the barrier layer 512 is configured to collect the magnetic field lines generated from the charging element 55 and thus block the electromagnetic induction effect caused by the electromagnetic field provided from the charging element 55 and the conductive layer 511. Further, the eddy current generated from the electromagnetic induction effect may be reduced. The inductance and quality factor of the charging element 55 may be increased and the charge efficiency of the electronic device 5 may be improved.

The printed circuit board 53 may include a conductive layer 531 and a dielectric layer 534. In some embodiments of the present disclosure, the conductive layer 531 includes a circuit layer. In some embodiments of the present disclosure, the conductive layer 531 includes a metal layer. In some embodiments of the present disclosure, the conductive layer 531 includes a Cu layer. In some embodiments of the present disclosure, the conductive layer 531 includes a ground layer. In some embodiments, the dielectric layer 534 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like.

Moreover, the printed circuit board 53 may include a barrier layer 532. The barrier layer 532 may include a magnetic permeable material. In some embodiments of the present disclosure, the barrier layer 532 includes a conductive material. In some embodiments of the present disclosure, the barrier layer 532 includes a non-conducting material. In some embodiments of the present disclosure, the barrier layer 532 abuts the conductive layer 531. That is, the barrier layer 532 may be embedded in the printed circuit board 53 and covered by the dielectric layer 534. In some embodiments of the present disclosure, the barrier layer 532 is disposed on a surface 535 (e.g., an upper surface) of the printed circuit board 53. That is, the barrier layer 532 may cover the dielectric layer 534 of the printed circuit board 53. Given the above, the barrier layer 532 is arranged between the charging element 55 and the conductive layer 531. The barrier layer 532 may have a substantially circular area. The peripheral of the circular area of the barrier layer 532 may substantially conform to the outer edge of the ring-shaped charging element 55. That is, the barrier layer 532 may fully cover the charging element 55 and an area surrounded by the charging element 55. Thus, in a bottom view perspective, the barrier layer 532 may overlap the charging element 55. As stated above, the ring-shaped body of the charging element 55 may have the gap, and thus the circular area of the barrier layer 532 may have a blank corresponding to the gap of the charging element 55.

As stated above, when the external device is put into the electronic device 5 and located at the gap of the charging element 55, the charging element 55 is driven to generate the electromagnetic field so that the external device is electrically coupled to the charging element 55 and charged by the electronic device 5. The conductive layer 531 forms an EMI shielding layer which is configured to shield an outside from the electromagnetic field produced by the charging element 55. The magnetic field lines generated from the charging element 55 may reach the barrier layer 532 before reaching the conductive layer 531 since a distance between the charging element 55 and the barrier layer 532 is shorter than a distance between the charging element 55 and the conductive layer 531. Therefore, the barrier layer 532 is configured to collect the magnetic field lines generated from the charging element 55 and thus block the electromagnetic induction effect caused by the electromagnetic field provided from the charging element 55 and the conductive layer 531. Further, the eddy current generated from the electromagnetic induction effect may be reduced. The inductance and quality factor of the charging element 55 may be increased and the charge efficiency of the electronic device 5 may be improved.

Referring to FIG. 5A, the charging element 55 may be arranged between the printed circuit board 51 with the conductive layer 511 and the printed circuit board 53 with the conductive layer 531. That is, the conductive layer 511 may be above the charging element 55 and the conductive layer 531 may be underneath the charging element 55. Thus, the conductive layer 511 and the conductive layer 531 are configured to accommodate loops of the electromagnetic field generated by the charging element 55.

The interposer 52 is disposed or mounted on the surface 535 of the printed circuit board 53, and is configured to support the printed circuit board 51. The interposer 52 may include an interconnection structure 521 and the dielectric layer 524. In some embodiments, the dielectric layer 524 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like. In some embodiments of the present disclosure, a plurality of electrical connections 529 is arranged between the surface 535 of the printed circuit board 53 and the interposer 52 so as to electrically connect printed circuit board 53 to the interposer 52. The electrical connection 529 may include a solder ball or a solder bump such as a C4 bump. In some embodiments of the present disclosure, a plurality of electrical connections 528 is arranged between the surface 516 of the printed circuit board 51 and the interposer 52 so as to electrically connect printed circuit board 51 to the interposer 52. The electrical connection 528 may include a solder ball or a solder bump such as a C4 bump. In some embodiments of the present disclosure, the interconnection structure 521 forms an EMI shielding layer. In some embodiments of the present disclosure, the electrical connection 528 and/or the electrical connection 529 may be a part of the EMI shielding layer. In other words, the conductive layers 511, 531, the interconnection structure 521 and the electrical connection 528 and/or the electrical connection 529 are collectively configured to block the electromagnetic field.

In addition, the interposer 52 may include a barrier layer 522. The barrier layer 522 may include a magnetic permeable material. In some embodiments of the present disclosure, the barrier layer 522 includes a conductive material. In some embodiments of the present disclosure, the barrier layer 522 includes a non-conducting material. In some embodiments of the present disclosure, the barrier layer 522 abuts the interconnection structure 521. That is, the barrier layer 522 may be embedded in the interposer 52 and covered by the dielectric layer 524. In some embodiments of the present disclosure, the barrier layer 522 is disposed on a surface 525 (e.g., an inner surface) of the interposer 52. That is, the barrier layer 522 may cover the dielectric layer 524 of the interposer 52. Given the above, the barrier layer 522 is arranged between the charging element 55 and the interconnection structure 521.

As stated above, when the external device is put into the electronic device 5 and located at the gap of the charging element 55, the charging element 55 is driven to generate the electromagnetic field so that the external device is electrically coupled to the charging element 55 and charged by the electronic device 5. The interconnection structure 521 forms an EMI shielding layer which is configured to shield an outside from the electromagnetic field produced by the charging element 55. The magnetic field lines generated from the charging element 55 may reach the barrier layer 522 before reaching the interconnection structure 521 since a distance between the charging element 55 and the barrier layer 522 is shorter than a distance between the charging element 55 and the interconnection structure 521. Therefore, the barrier layer 522 is configured to collect the magnetic field lines generated from the charging element 55 and thus block the electromagnetic induction effect caused by the electromagnetic field provided from the charging element 55 and the interconnection structure 521. Further, the eddy current generated from the electromagnetic induction effect may be reduced. The inductance and quality factor of the charging element 55 may be increased and the charge efficiency of the electronic device 5 may be improved.

FIG. 5B illustrates a schematic cross-sectional view along line B-B in FIG. 5A. As shown in FIG. 5B, the barrier layer 522 may substantially surround the charging element 55. In addition, the interconnection structure 521 may substantially surround the charging element 55 as well.

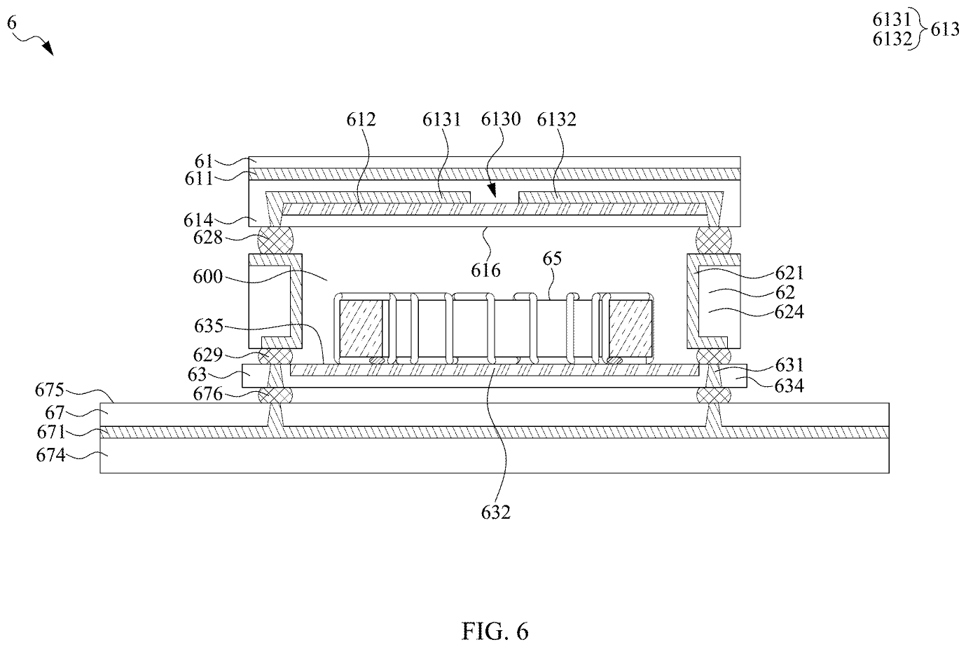

FIG. 6 is a schematic cross-sectional view of an electronic device 6 in accordance with an embodiment of the instant disclosure. The electronic device 6 may include a printed circuit board 61 (e.g., an upper circuit board), an interposer 62, a printed circuit board 63 (e.g., a lower circuit board), a charging element 65 and a main circuit board 67. The interposer 62 is stacked on the printed circuit board 63 and the printed circuit board 61 is stacked on the interposer 62. That is, the interposer 62 is disposed on the printed circuit board 63 and supports the printed circuit board 61. As the interposer 62 is stacked on the printed circuit board 63 and the printed circuit board 61 is stacked on the interposer 62, the printed circuit board 61, the interposer 62 and the printed circuit board 63 may define an inner space 600. Further, the charging element 65 may be arranged within the inner space 600 defined by the printed circuit board 61, the interposer 62 and the printed circuit board 63. In some embodiments of the present disclosure, the space 600 may include a package body surrounding the charging element 65. Referring to FIG. 6, an area of the printed circuit board 63 may be substantially identical to an area of the printed circuit board 61, and the printed circuit board 63 may be further mounted on the main circuit board 67. In other words, the printed circuit board 61, the interposer 62 and the circuit board 63 cooperatively form a module, and the module includes the charging element 65 and mounted to the main circuit board 67. In some embodiments of the present disclosure, the main circuit board 67 may be a part of another device. In other words, the interposer 62 defines an opening to accommodate the charging element 65.

In some embodiments of the present disclosure, the charging element 65 is the same as or similar to the charging element 15. That is, the charging element 65 may include an electromagnet and have a ring-shaped body with coils. Further, the ring-shaped body of the charging element 65 may have a gap.

Meanwhile, the printed circuit board 61 may have an opening substantially aligning with the gap of the charging element 65 and be in communicate with the inner space 600. That is, the opening of the printed circuit board 61 may provide a passage extending from outside of the electronic device 6 into the inside of the electronic device 6. That is, an external device could be put into the electronic device 6 and located at the gap of the charging element 65. When the external device is put into the electronic device 6 and located at the gap of the charging element 65, the charging element 65 is driven to generate the electromagnetic field so that the external device is electrically coupled to the charging element 65 and charged by the electronic device 6.

The printed circuit board 61 may include conductive layers 611 and 613 and the dielectric layer 614. In some embodiments of the present disclosure, the conductive layer 611, 613 includes a circuit layer. In some embodiments of the present disclosure, the conductive layer 611, 613 includes a metal layer. In some embodiments of the present disclosure, the conductive layer 611, 613 includes a Cu layer. In some embodiments, the dielectric layer 614 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like.

As shown in FIG. 6, the conductive layer 611 is arranged above the conductive layer 613. That is, the conductive layer 613 covers the charging element 65 and the conductive layer 611 covers the conductive layer 613 and the charging element 611. The conductive layer 613 may include a plurality of separated portions 6131 and 6132. The portions 6131 and 6132 are separated from each other. Referring to FIG. 6, the portions 6131 and 6132 are spaced apart from each other and a gap 6130 is formed between the portions 6131 and 6132. Further, the conductive layer 611 may cover the gap 6130 between the portions 6131 and 6132 of the conductive layer 613.

As stated above, when the external device is put into the electronic device 6 and located at the gap of the charging element 65, the charging element 65 is driven to generate the electromagnetic field so that the external device is electrically coupled to the charging element 65 and charged by the electronic device 6. The conductive layers 611 and 613 form an EMI shielding layer which is configured to shield an outside from the electromagnetic field produced by the charging element 65. Meanwhile, since the conductive layer 613 includes multiple separated portions 6131 and 6132, the eddy current generated from an electromagnetic induction effect caused by an electromagnetic field of the charging element 65 and the conductive layer(s) 611 and/or 613 is divided into multiple small size eddy currents which could not be gathered. Thus, negative effects caused by the eddy current may be reduced. The inductance and quality factor of the charging element 65 may be increased and the charge efficiency of the electronic device 6 may be improved. In addition, since the conductive layer 611 may cover the gap 6130 between the portions 6131 and 6132 of the conductive layer 613, the conductive layer 611 may block a stray magnetic field passing through the gap 6130.

Moreover, the printed circuit board 61 may include a barrier layer 612. The barrier layer 612 may include a magnetic permeable material. In some embodiments of the present disclosure, the barrier layer 612 includes a conductive material. In some embodiments of the present disclosure, the barrier layer 612 includes a non-conducting material. In some embodiments of the present disclosure, the barrier layer 612 abuts the conductive layer 613. That is, the barrier layer 612 may be embedded in the printed circuit board 61 and covered by the dielectric layer 614. In some embodiments of the present disclosure, the barrier layer 612 is disposed on a surface 616 (e.g., a lower surface) of the printed circuit board 61. That is, the barrier layer 612 may cover the dielectric layer 614 of the printed circuit board 61. Given the above, the barrier layer 612 is arranged between the charging element 65 and the conductive layers 611, 613. The barrier layer 612 may have a substantially circular area. The peripheral of the circular area of the barrier layer 612 may substantially conform to the outer edge of the ring-shaped charging element 65. That is, the barrier layer 612 may fully cover the charging element 65 and an area surrounded by the charging element 65. Thus, in a top view perspective, the barrier layer 612 may overlap the charging element 65. As stated above, the ring-shaped body of the charging element 65 may have the gap, and thus the circular area of the barrier layer 612 may have a blank corresponding to the gap of the charging element 65.

As stated above, when the external device is put into the electronic device 6 and located at the gap of the charging element 65, the charging element 65 is driven to generate the electromagnetic field so that the external device is electrically coupled to the charging element 65 and charged by the electronic device 6. The magnetic field lines generated from the charging element 65 may reach the barrier layer 612 before reaching the conductive layer 613 since a distance between the charging element 65 and the barrier layer 612 is shorter than a distance between the charging element 65 and the conductive layer 613. Therefore, the barrier layer 612 is configured to collect the magnetic field lines generated from the charging element 45 and thus block the electromagnetic induction effect caused by the electromagnetic field provided from the charging element 65 and the conductive layer 613. Further, the eddy current generated from the electromagnetic induction effect may be reduced. The inductance and quality factor of the charging element 65 may be increased and the charge efficiency of the electronic device 6 may be improved.

The printed circuit board 63 may provide a barrier layer 632. In some embodiments of the present disclosure, the printed circuit board 63 includes a dummy board. That is, the printed circuit board 63 may include an interconnection structure 631 and a dielectric layer 634. The interconnection structure 631 may be configured to electrically connect the printed circuit board 61 and/or the interposer 62 to the main circuit board 67. In some embodiments, the dielectric layer 634 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like. Thus, a thickness of the printed circuit board 63 may be smaller than a thickness of the printed circuit board 61.

The barrier layer 632 may include a magnetic permeable material. In some embodiments of the present disclosure, the barrier layer 632 includes a conductive material. In some embodiments of the present disclosure, the barrier layer 632 includes a non-conducting material. In some embodiments of the present disclosure, the barrier layer 632 is embedded in the printed circuit board 63 and covered by the dielectric layer 634. In some embodiments of the present disclosure, the barrier layer 632 is disposed on a surface 635 (e.g., an upper surface) of the printed circuit board 63. That is, the barrier layer 632 may cover the dielectric layer 634 of the printed circuit board 63. The barrier layer 632 may have a substantially circular area. The peripheral of the circular area of the barrier layer 632 may substantially conform to the outer edge of the ring-shaped charging element 65. That is, the barrier layer 632 may fully cover the charging element 65 and an area surrounded by the charging element 65. Thus, in a bottom view perspective, the barrier layer 632 may overlap the charging element 65. As stated above, the ring-shaped body of the charging element 65 may have the gap, and thus the circular area of the barrier layer 632 may have a blank corresponding to the gap of the charging element 65.

Moreover, the printed circuit board 67 may support the printed circuit board 63. That is, the printed circuit board 63 is mounted on a surface 675 (e.g., an upper surface) of the printed circuit board 67. The printed circuit board 67 may include a conductive layer 671 and a dielectric layer 674. In some embodiments of the present disclosure, the conductive layer 671 includes a circuit layer. In some embodiments of the present disclosure, the conductive layer 671 includes a metal layer. In some embodiments of the present disclosure, the conductive layer 671 includes a Cu layer. In some embodiments of the present disclosure, the conductive layer 671 includes a ground layer. In some embodiments, the dielectric layer 674 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like. In some embodiments of the present disclosure, a plurality of electrical connections 676 is arranged between the surface 675 of the printed circuit board 67 and the printed circuit board 63 so as to electrically connect printed circuit board 63 to the printed circuit board 67. The electrical connection 676 may include a solder ball or a solder bump such as a C4 bump.

As stated above, when the external device is put into the electronic device 6 and located at the gap of the charging element 65, the charging element 65 is driven to generate the electromagnetic field so that the external device is electrically coupled to the charging element 65 and charged by the electronic device 6. The conductive layer 671 of the printed circuit board 67 forms an EMI shielding layer which is configured to shield an outside from the electromagnetic field produced by the charging element 65. The magnetic field lines generated from the charging element 65 may reach the barrier layer 632 of the printed circuit board 63 before reaching the conductive layer 671 of the printed circuit board 67 since a distance between the charging element 65 and the barrier layer 632 is shorter than a distance between the charging element 65 and the conductive layer 671. Therefore, the barrier layer 632 is configured to collect the magnetic field lines generated from the charging element 65 and thus block the electromagnetic induction effect caused by the electromagnetic field provided from the charging element 65 and the conductive layer 671. Further, the eddy current generated from the electromagnetic induction effect may be reduced. The inductance and quality factor of the charging element 65 may be increased and the charge efficiency of the electronic device 6 may be improved.

Referring to FIG. 6, the charging element 65 may be arranged between the printed circuit board 61 with the conductive layers 611 and 613 and the printed circuit board 67 with the conductive layer 631. That is, the conductive layers 611 and 613 may be above the charging element 65 and the conductive layer 671 may be underneath the charging element 65. Thus, the conductive layers 611 and 613 and the conductive layer 631 are configured to accommodate loops of the electromagnetic field generated by the charging element 65.

The interposer 62 is disposed or mounted on the surface 635 of the printed circuit board 63, and is configured to support the printed circuit board 61. The interposer 62 may include an interconnection structure 621 and a dielectric layer 624. In some embodiments, the dielectric layer 624 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like. In some embodiments of the present disclosure, a plurality of electrical connections 629 is arranged between the surface 635 of the printed circuit board 63 and the interposer 62 so as to electrically connect printed circuit board 63 to the interposer 62. The electrical connection 629 may include a solder ball or a solder bump such as a C4 bump. In some embodiments of the present disclosure, a plurality of electrical connections 628 is arranged between the surface 616 of the printed circuit board 61 and the interposer 62 so as to electrically connect printed circuit board 61 to the interposer 62. The electrical connection 628 may include a solder ball or a solder bump such as a C4 bump. In some embodiments of the present disclosure, the interconnection structure 621 forms an EMI shielding layer. In some embodiments of the present disclosure, the electrical connection 628 and/or the electrical connection 629 may be a part of the EMI shielding layer. In other words, the conductive layers 611, 613, 671, the interconnection structure 621 and the electrical connection 628 and/or the electrical connection 629 are collectively configured to block the electromagnetic field. Further,

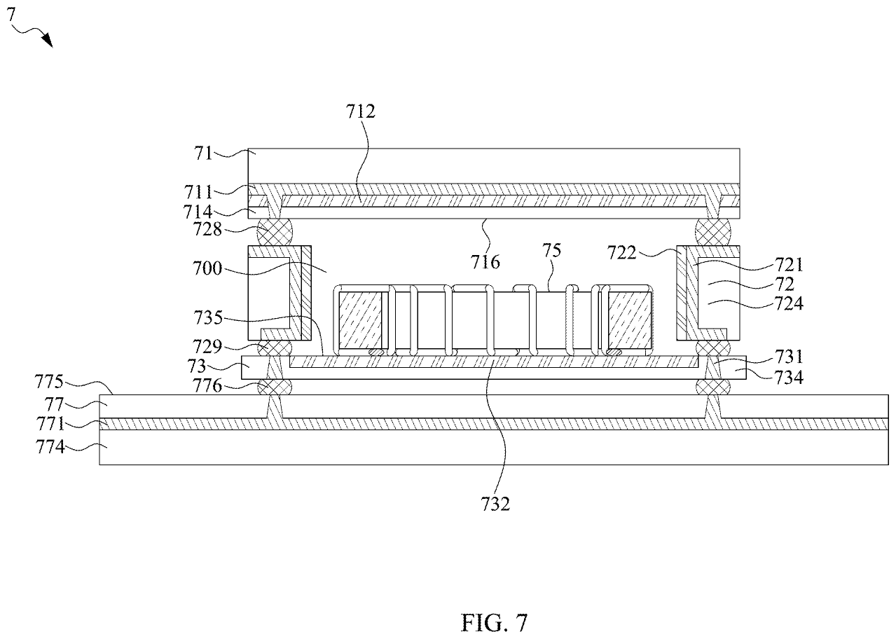

FIG. 7 is a schematic cross-sectional view of an electronic device 7 in accordance with an embodiment of the instant disclosure. The electronic device 7 may include a printed circuit board 71 (e.g., an upper circuit board), an interposer 72, a printed circuit board 73 (e.g., a lower circuit board), a charging element 75 and a main circuit board 77. The interposer 72 is stacked on the printed circuit board 73 and the printed circuit board 71 is stacked on the interposer 72. That is, the interposer 72 is disposed on the printed circuit board 73 and supports the printed circuit board 71. As the interposer 72 is stacked on the printed circuit board 73 and the printed circuit board 71 is stacked on the interposer 72, the printed circuit board 71, the interposer 72 and the printed circuit board 73 may define an inner space 700. Further, the charging element 75 may be arranged within the inner space 700 defined by the printed circuit board 71, the interposer 72 and the printed circuit board 73. In some embodiments of the present disclosure, the space 700 may include a package body surrounding the charging element 75. Referring to FIG. 7, an area of the printed circuit board 73 may be substantially identical to an area of the printed circuit board 71, and the printed circuit board 73 may be further mounted on the main circuit board 77. In other words, the printed circuit board 71, the interposer 72 and the circuit board 73 cooperatively form a module, and the module includes the charging element 75 and mounted to the main circuit board 77. In some embodiments of the present disclosure, the main circuit board 77 may be a part of another device. In other words, the interposer 72 defines an opening to accommodate the charging element 75.

In some embodiments of the present disclosure, the charging element 75 is the same as or similar to the charging element 15. That is, the charging element 75 may include an electromagnet and have a ring-shaped body with coils. Further, the ring-shaped body of the charging element 75 may have a gap.

Meanwhile, the printed circuit board 71 may have an opening substantially aligning with the gap of the charging element 75 and be in communicate with the inner space 700. That is, the opening of the printed circuit board 71 may provide a passage extending from outside of the electronic device 7 into the inside of the electronic device 7. That is, an external device could be put into the electronic device 7 and located at the gap of the charging element 75. When the external device is put into the electronic device 7 and located at the gap of the charging element 75, the charging element 75 is driven to generate the electromagnetic field so that the external device is electrically coupled to the charging element 75 and charged by the electronic device 7.

Referring to FIG. 7, the printed circuit board 71 may include a conductive layer 711 and a dielectric layer 714. In some embodiments of the present disclosure, the conductive layer 711 includes a circuit layer. In some embodiments of the present disclosure, the conductive layer 711 includes a metal layer. In some embodiments of the present disclosure, the conductive layer 711 includes a Cu layer. In some embodiments, the dielectric layer 714 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like.

Moreover, the printed circuit board 71 may include a barrier layer 712. The barrier layer 712 may include a magnetic permeable material. In some embodiments of the present disclosure, the barrier layer 712 includes a conductive material. In some embodiments of the present disclosure, the barrier layer 712 includes a non-conducting material. In some embodiments of the present disclosure, the barrier layer 712 abuts the conductive layer 711. That is, the barrier layer 712 may be embedded in the printed circuit board 71 and covered by the dielectric layer 714. In some embodiments of the present disclosure, the barrier layer 712 is disposed on a surface 716 (e.g., a lower surface) of the printed circuit board 71. That is, the barrier layer 712 may cover the dielectric layer 714 of the printed circuit board 71. Given the above, the barrier layer 712 is arranged between the charging element 75 and the conductive layer 711. The barrier layer 712 may have a substantially circular area. The peripheral of the circular area of the barrier layer 712 may substantially conform to the outer edge of the ring-shaped charging element 75. That is, the barrier layer 712 may fully cover the charging element 75 and an area surrounded by the charging element 75. Thus, in a top view perspective, the barrier layer 712 may overlap the charging element 75. As stated above, the ring-shaped body of the charging element 75 may have the gap, and thus the circular area of the barrier layer 712 may have a blank corresponding to the gap of the charging element 75.

As stated above, when the external device is put into the electronic device 5 and located at the gap of the charging element 55, the charging element 55 is driven to generate the electromagnetic field so that the external device is electrically coupled to the charging element 55 and charged by the electronic device 5. The conductive layer 511 forms an EMI shielding layer which is configured to shield an outside from the electromagnetic field produced by the charging element 55. The magnetic field lines generated from the charging element 55 may reach the barrier layer 512 before reaching the conductive layer 511 since a distance between the charging element 55 and the barrier layer 512 is shorter than a distance between the charging element 55 and the conductive layer 511. Therefore, the barrier layer 512 is configured to collect the magnetic field lines generated from the charging element 55 and thus block the electromagnetic induction effect caused by the electromagnetic field provided from the charging element 55 and the conductive layer 511. Further, the eddy current generated from the electromagnetic induction effect may be reduced. The inductance and quality factor of the charging element 55 may be increased and the charge efficiency of the electronic device 5 may be improved.

As stated above, when the external device is put into the electronic device 7 and located at the gap of the charging element 75, the charging element 75 is driven to generate the electromagnetic field so that the external device is electrically coupled to the charging element 75 and charged by the electronic device 7. The conductive layer 711 forms an EMI shielding layer which is configured to shield an outside from the electromagnetic field produced by the charging element 75. The magnetic field lines generated from the charging element 75 may reach the barrier layer 712 before reaching the conductive layer 711 since a distance between the charging element 75 and the barrier layer 712 is shorter than a distance between the charging element 75 and the conductive layer 711. Therefore, the barrier layer 712 is configured to collect the magnetic field lines generated from the charging element 75 and thus block the electromagnetic induction effect caused by the electromagnetic field provided from the charging element 75 and the conductive layer 711. Further, the eddy current generated from the electromagnetic induction effect may be reduced. The inductance and quality factor of the charging element 75 may be increased and the charge efficiency of the electronic device 7 may be improved.

The printed circuit board 73 may provide a barrier layer 732. In some embodiments of the present disclosure, the printed circuit board 73 includes a dummy board. That is, the printed circuit board 73 may include an interconnection structure 731 and a dielectric layer 734. The interconnection structure 731 may be configured to electrically connect the printed circuit board 71 and/or the interposer 72 to the main circuit board 77. In some embodiments, the dielectric layer 734 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like. Thus, a thickness of the printed circuit board 73 may be smaller than a thickness of the printed circuit board 71.

The barrier layer 732 may include a magnetic permeable material. In some embodiments of the present disclosure, the barrier layer 732 includes a conductive material. In some embodiments of the present disclosure, the barrier layer 732 includes a non-conducting material. In some embodiments of the present disclosure, the barrier layer 732 is embedded in the printed circuit board 73 and covered by the dielectric layer 734. In some embodiments of the present disclosure, the barrier layer 732 is disposed on a surface 735 (e.g., an upper surface) of the printed circuit board 73. That is, the barrier layer 732 may cover the dielectric layer 734 of the printed circuit board 73. The barrier layer 732 may have a substantially circular area. The peripheral of the circular area of the barrier layer 732 may substantially conform to the outer edge of the ring-shaped charging element 75. That is, the barrier layer 732 may fully cover the charging element 75 and an area surrounded by the charging element 75. Thus, in a bottom view perspective, the barrier layer 732 may overlap the charging element 75. As stated above, the ring-shaped body of the charging element 75 may have the gap, and thus the circular area of the barrier layer 732 may have a blank corresponding to the gap of the charging element 75.

Moreover, the printed circuit board 77 may support the printed circuit board 73. That is, the printed circuit board 73 is mounted on a surface 775 (e.g., an upper surface) of the printed circuit board 77. The printed circuit board 77 may include a conductive layer 771 and a dielectric layer 774. In some embodiments of the present disclosure, the conductive layer 771 includes a circuit layer. In some embodiments of the present disclosure, the conductive layer 771 includes a metal layer. In some embodiments of the present disclosure, the conductive layer 771 includes a Cu layer. In some embodiments of the present disclosure, the conductive layer 771 includes a ground layer. In some embodiments, the dielectric layer 774 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like. In some embodiments of the present disclosure, a plurality of electrical connections 776 is arranged between the surface 775 of the printed circuit board 77 and the printed circuit board 73 so as to electrically connect printed circuit board 73 to the printed circuit board 77. The electrical connection 776 may include a solder ball or a solder bump such as a C4 bump.

As stated above, when the external device is put into the electronic device 6 and located at the gap of the charging element 75, the charging element 75 is driven to generate the electromagnetic field so that the external device is electrically coupled to the charging element 75 and charged by the electronic device 7. The conductive layer 771 of the printed circuit board 77 forms an EMI shielding layer which is configured to shield an outside from the electromagnetic field produced by the charging element 75. The magnetic field lines generated from the charging element 75 may reach the barrier layer 732 of the printed circuit board 73 before reaching the conductive layer 771 of the printed circuit board 77 since a distance between the charging element 75 and the barrier layer 732 is shorter than a distance between the charging element 75 and the conductive layer 771. Therefore, the barrier layer 732 is configured to collect the magnetic field lines generated from the charging element 75 and thus block the electromagnetic induction effect caused by the electromagnetic field provided from the charging element 75 and the conductive layer 771. Further, the eddy current generated from the electromagnetic induction effect may be reduced. The inductance and quality factor of the charging element 75 may be increased and the charge efficiency of the electronic device 6 may be improved.

Referring to FIG. 7, the charging element 75 may be arranged between the printed circuit board 71 with the conductive layers 711 and 713 and the printed circuit board 77 with the conductive layer 731. That is, the conductive layers 711 and 713 may be above the charging element 75 and the conductive layer 771 may be underneath the charging element 75. Thus, the conductive layers 711 and 713 and the conductive layer 731 are configured to accommodate loops of the electromagnetic field generated by the charging element 75.

The interposer 72 is disposed or mounted on the surface 735 of the printed circuit board 63, and is configured to support the printed circuit board 71. The interposer 72 may include an interconnection structure 721 and a dielectric layer 724. In some embodiments, the dielectric layer 724 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like. In some embodiments of the present disclosure, a plurality of electrical connections 729 is arranged between the surface 735 of the printed circuit board 73 and the interposer 72 so as to electrically connect printed circuit board 73 to the interposer 72. The electrical connection 729 may include a solder ball or a solder bump such as a C4 bump. In some embodiments of the present disclosure, a plurality of electrical connections 728 is arranged between the surface 716 of the printed circuit board 71 and the interposer 72 so as to electrically connect printed circuit board 71 to the interposer 72. The electrical connection 728 may include a solder ball or a solder bump such as a C4 bump. In some embodiments of the present disclosure, the interconnection structure 721 forms an EMI shielding layer. In some embodiments of the present disclosure, the electrical connection 728 and/or the electrical connection 729 may be a part of the EMI shielding layer. In other words, the conductive layers 711, 771, the interconnection structure 721 and the electrical connection 728 and/or the electrical connection 729 are collectively configured to block the electromagnetic field.

In addition, the interposer 72 may include a barrier layer 722. The barrier layer 722 may include a magnetic permeable material. In some embodiments of the present disclosure, the barrier layer 722 includes a conductive material. In some embodiments of the present disclosure, the barrier layer 722 includes a non-conducting material. In some embodiments of the present disclosure, the barrier layer 722 abuts the interconnection structure 721. That is, the barrier layer 722 may be embedded in the interposer 72 and covered by the dielectric layer 724. In some embodiments of the present disclosure, the barrier layer 722 is disposed on a surface 725 (e.g., an inner surface) of the interposer 72. That is, the barrier layer 722 may cover the dielectric layer 724 of the interposer 72. Given the above, the barrier layer 722 is arranged between the charging element 75 and the interconnection structure 721.

As stated above, when the external device is put into the electronic device 7 and located at the gap of the charging element 75, the charging element 75 is driven to generate the electromagnetic field so that the external device is electrically coupled to the charging element 75 and charged by the electronic device 7. The interconnection structure 721 forms an EMI shielding layer which is configured to shield an outside from the electromagnetic field produced by the charging element 75. The magnetic field lines generated from the charging element 75 may reach the barrier layer 722 before reaching the interconnection structure 721 since a distance between the charging element 75 and the barrier layer 722 is shorter than a distance between the charging element 75 and the interconnection structure 721. Therefore, the barrier layer 722 is configured to collect the magnetic field lines generated from the charging element 75 and thus block the electromagnetic induction effect caused by the electromagnetic field provided from the charging element 75 and the interconnection structure 721. Further, the eddy current generated from the electromagnetic induction effect may be reduced. The inductance and quality factor of the charging element 75 may be increased and the charge efficiency of the electronic device 7 may be improved.

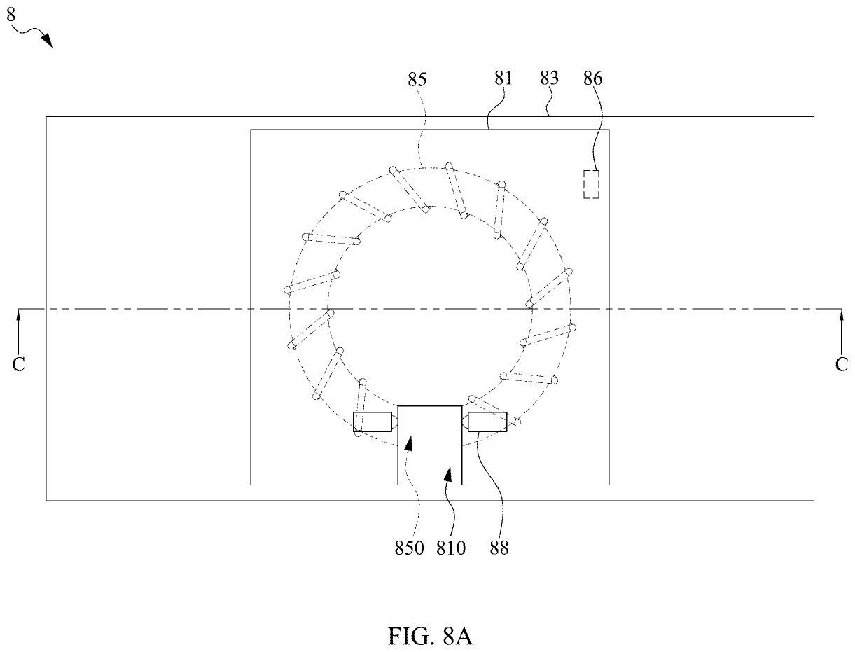

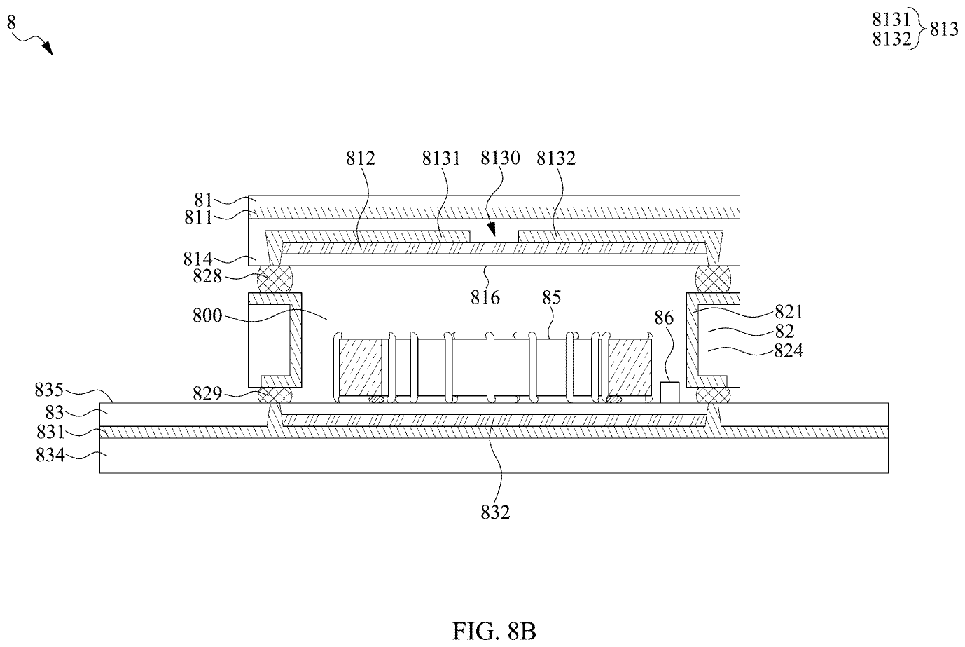

FIG. 8A is a top view of an electronic device 8 in accordance with an embodiment of the instant disclosure. FIG. 8B illustrates a schematic cross-sectional view along line C-C in FIG. 8A. The electronic device 8 may include a printed circuit board 81 (e.g., an upper circuit board), an interposer 82, a printed circuit board 83 (e.g., a lower circuit board) and a charging element 85. The interposer 82 is stacked on the printed circuit board 83 and the printed circuit board 81 is stacked on the interposer 82. That is, the interposer 82 is disposed on the printed circuit board 83 and supports the printed circuit board 81. As the interposer 82 is stacked on the printed circuit board 83 and the printed circuit board 81 is stacked on the interposer 82, the printed circuit board 81, the interposer 82 and the printed circuit board 83 may define an inner space 800. Further, the charging element 85 may be arranged within the inner space 800 defined by the printed circuit board 81, the interposer 82 and the printed circuit board 83. In some embodiments of the present disclosure, the space 800 may include a package body surrounding the charging element 85. Referring to FIG. 8A, the printed circuit board 81 may include a square shape. Since the printed circuit board 61 may include a square shape, the space 800 may have more capacity to receive more components. As shown in FIGS. 8A and 8B, an electronic component 86 is mounted on the printed circuit board 83, and the electronic component 86 and the charging element 85 are disposed side by side. Further, an area of the printed circuit board 83 may be larger than an area of the printed circuit board 81. In other words, the printed circuit board 81 and the interposer 822 cooperatively form a cap mounted on the printed circuit board 83, and the charging element 85 is mounted on the printed circuit board 83 and covered by the cap formed by the printed circuit board 81 and the interposer 82. In other words, the interposer 82 defines an opening to accommodate the charging element 85.

In some embodiments of the present disclosure, the charging element 85 includes an electromagnet. In some embodiments of the present disclosure, the charging element 85 includes a coil unit. Referring to FIG. 8A, the electromagnet may have a ring-shaped body with coils. Further, the ring-shaped body of the charging element 85 may have a gap 850. That is, the charging element 85 includes a breach.

Meanwhile, the printed circuit board 81 may have an opening 810 substantially aligning with the gap 850 of the charging element 85 and be in communicate with the inner space 800. That is, the opening 810 of the printed circuit board 81 may provide a passage extending from outside of the electronic device 8 into the inside of the electronic device 8. That is, an external device could be put into the electronic device 8 and located at the gap 850 of the charging element 85. When the external device is put into the electronic device 8 and located at the gap 850 of the charging element 85, the charging element 85 is driven to generate the electromagnetic field so that the external device is electrically coupled to the charging element 85 and charged by the electronic device 8. In some embodiments of the present disclosure, an electronic component 88 may be mounted or disposed on the printed circuit board 81. In some embodiments of the present disclosure, the electronic component 88 is an IR sensor.

The printed circuit board 81 may include conductive layers 811 and 813 and the dielectric layer 814. In some embodiments of the present disclosure, the conductive layer 811, 813 includes a circuit layer. In some embodiments of the present disclosure, the conductive layer 811, 813 includes a metal layer. In some embodiments of the present disclosure, the conductive layer 811, 813 includes a Cu layer. In some embodiments, the dielectric layer 814 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like.

As shown in FIG. 8B, the conductive layer 811 is arranged above the conductive layer 813. That is, the conductive layer 813 covers the charging element 85 and the conductive layer 811 covers the conductive layer 813 and the charging element 811. The conductive layer 813 may include a plurality of separated portions 8131 and 8132. The portions 8131 and 8132 are separated from each other. Referring to FIG. 8, the portions 8131 and 8132 are spaced apart from each other and a gap 8130 is formed between the portions 8131 and 8132. Further, the conductive layer 811 may cover the gap 8130 between the portions 8131 and 8132 of the conductive layer 813.

As stated above, when the external device is put into the electronic device 8 and located at the gap 850 of the charging element 85, the charging element 85 is driven to generate the electromagnetic field so that the external device is electrically coupled to the charging element 85 and charged by the electronic device 8. The conductive layers 811 and 813 form an EMI shielding layer which is configured to shield an outside from the electromagnetic field produced by the charging element 85. Meanwhile, since the conductive layer 813 includes multiple separated portions 8131 and 8132, the eddy current generated from an electromagnetic induction effect caused by an electromagnetic field of the charging element 85 and the conductive layer(s) 811 and/or 813 is divided into multiple small size eddy currents which could not be gathered. Thus, negative effects caused by the eddy current may be reduced. The inductance and quality factor of the charging element 85 may be increased and the charge efficiency of the electronic device 8 may be improved. In addition, since the conductive layer 811 may cover the gap 8130 between the portions 8131 and 8132 of the conductive layer 813, the conductive layer 811 may block a stray magnetic field passing through the gap 8130.

Moreover, the printed circuit board 81 may include a barrier layer 812. The barrier layer 812 may include a magnetic permeable material. In some embodiments of the present disclosure, the barrier layer 812 includes a conductive material. In some embodiments of the present disclosure, the barrier layer 812 includes a non-conducting material. In some embodiments of the present disclosure, the barrier layer 812 abuts the conductive layer 813. That is, the barrier layer 812 may be embedded in the printed circuit board 81 and covered by the dielectric layer 814. In some embodiments of the present disclosure, the barrier layer 812 is disposed on a surface 816 (e.g., a lower surface) of the printed circuit board 81. That is, the barrier layer 812 may cover the dielectric layer 814 of the printed circuit board 81. Given the above, the barrier layer 812 is arranged between the charging element 85 and the conductive layers 811, 813. The barrier layer 812 may have a substantially circular area. The peripheral of the circular area of the barrier layer 812 may substantially conform to the outer edge of the ring-shaped charging element 85. That is, the barrier layer 812 may fully cover the charging element 85 and an area surrounded by the charging element 85. Thus, in a top view perspective, the barrier layer 812 may overlap the charging element 85. As stated above, the ring-shaped body of the charging element 85 may have the gap 850, and thus the circular area of the barrier layer 812 may have a blank corresponding to the gap 850 of the charging element 85.

As stated above, when the external device is put into the electronic device 8 and located at the gap 850 of the charging element 85, the charging element 85 is driven to generate the electromagnetic field so that the external device is electrically coupled to the charging element 85 and charged by the electronic device 8. The magnetic field lines generated from the charging element 85 may reach the barrier layer 812 before reaching the conductive layer 813 since a distance between the charging element 85 and the barrier layer 812 is shorter than a distance between the charging element 85 and the conductive layer 813. Therefore, the barrier layer 812 is configured to collect the magnetic field lines generated from the charging element 85 and thus block the electromagnetic induction effect caused by the electromagnetic field provided from the charging element 85 and the conductive layer 813. Further, the eddy current generated from the electromagnetic induction effect may be reduced. The inductance and quality factor of the charging element 85 may be increased and the charge efficiency of the electronic device 8 may be improved.

The printed circuit board 83 may include a conductive layer 831 and a dielectric layer 834. In some embodiments of the present disclosure, the conductive layer 831 includes a circuit layer. In some embodiments of the present disclosure, the conductive layer 831 includes a metal layer. In some embodiments of the present disclosure, the conductive layer 831 includes a Cu layer. In some embodiments of the present disclosure, the conductive layer 831 includes a ground layer. In some embodiments, the dielectric layer 834 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like.

Moreover, the printed circuit board 83 may include a barrier layer 832. The barrier layer 832 may include a magnetic permeable material. In some embodiments of the present disclosure, the barrier layer 832 includes a conductive material. In some embodiments of the present disclosure, the barrier layer 832 includes a non-conducting material. In some embodiments of the present disclosure, the barrier layer 832 abuts the conductive layer 831. That is, the barrier layer 832 may be embedded in the printed circuit board 83 and covered by the dielectric layer 834. In some embodiments of the present disclosure, the barrier layer 832 is disposed on a surface 835 (e.g., an upper surface) of the printed circuit board 83. That is, the barrier layer 832 may cover the dielectric layer 834 of the printed circuit board 83. Given the above, the barrier layer 832 is arranged between the charging element 85 and the conductive layer 831. The barrier layer 832 may have a substantially circular area. The peripheral of the circular area of the barrier layer 832 may substantially conform to the outer edge of the ring-shaped charging element 85. That is, the barrier layer 832 may fully cover the charging element 85 and an area surrounded by the charging element 85. Thus, in a bottom view perspective, the barrier layer 832 may overlap the charging element 85. As stated above, the ring-shaped body of the charging element 85 may have the gap 850, and thus the circular area of the barrier layer 832 may have a blank corresponding to the gap 850 of the charging element 85.

As stated above, when the external device is put into the electronic device 8 and located at the gap 850 of the charging element 85, the charging element 85 is driven to generate the electromagnetic field so that the external device is electrically coupled to the charging element 85 and charged by the electronic device 8. The conductive layer 831 forms an EMI shielding layer which is configured to shield an outside from the electromagnetic field produced by the charging element 85. The magnetic field lines generated from the charging element 85 may reach the barrier layer 832 before reaching the conductive layer 831 since a distance between the charging element 85 and the barrier layer 832 is shorter than a distance between the charging element 85 and the conductive layer 831. Therefore, the barrier layer 832 is configured to collect the magnetic field lines generated from the charging element 85 and thus block the electromagnetic induction effect caused by the electromagnetic field provided from the charging element 85 and the conductive layer 831. Further, the eddy current generated from the electromagnetic induction effect may be reduced. The inductance and quality factor of the charging element 85 may be increased and the charge efficiency of the electronic device 4 may be improved.

Referring to FIG. 8B, the charging element 85 may be arranged between the printed circuit board 81 with the conductive layers 811 and 813 and the printed circuit board 83 with the conductive layer 831. That is, the conductive layers 811 and 813 may be above the charging element 85 and the conductive layer 431 may be underneath the charging element 85. Thus, the conductive layers 811 and 813 and the conductive layer 831 are configured to accommodate loops of the electromagnetic field generated by the charging element 85.

The interposer 82 is disposed or mounted on the surface 835 of the printed circuit board 83, and is configured to support the printed circuit board 81. The interposer 82 may include an interconnection structure 821 and the dielectric layer 824. In some embodiments, the dielectric layer 424 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like. In some embodiments of the present disclosure, a plurality of electrical connections 829 is arranged between the surface 835 of the printed circuit board 83 and the interposer 82 so as to electrically connect printed circuit board 83 to the interposer 82. The electrical connection 829 may include a solder ball or a solder bump such as a C4 bump. In some embodiments of the present disclosure, a plurality of electrical connections 828 is arranged between the surface 816 of the printed circuit board 81 and the interposer 82 so as to electrically connect printed circuit board 81 to the interposer 82. The electrical connection 828 may include a solder ball or a solder bump such as a C4 bump. In some embodiments of the present disclosure, the interconnection structure 821 forms an EMI shielding layer. In some embodiments of the present disclosure, the electrical connection 828 and/or the electrical connection 829 may be a part of the EMI shielding layer. In other words, the conductive layers 811, 813, 831, the interconnection structure 821 and the electrical connection 828 and/or the electrical connection 829 are collectively configured to block the electromagnetic field.

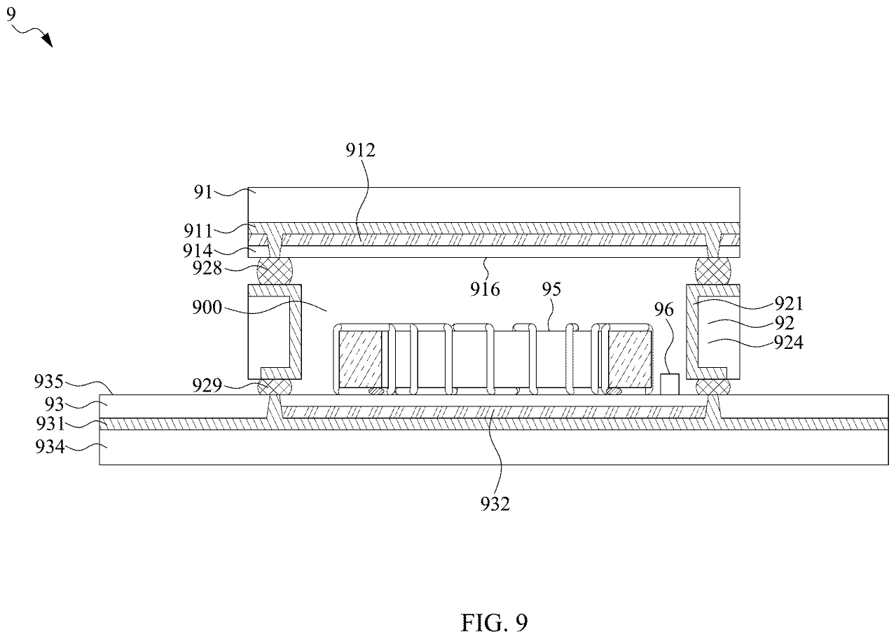

FIG. 9 is a schematic cross-sectional view of an electronic device 9 in accordance with an embodiment of the instant disclosure. The electronic device 9 may include a printed circuit board 91 (e.g., an upper circuit board), an interposer 92, a printed circuit board 93 (e.g., a lower circuit board) and a charging element 95. The interposer 92 is stacked on the printed circuit board 93 and the printed circuit board 91 is stacked on the interposer 92. That is, the interposer 92 is disposed on the printed circuit board 93 and supports the printed circuit board 91. As the interposer 92 is stacked on the printed circuit board 93 and the printed circuit board 91 is stacked on the interposer 92, the printed circuit board 91, the interposer 92 and the printed circuit board 93 may define an inner space 900. Further, the charging element 95 may be arranged within the inner space 900 defined by the printed circuit board 91, the interposer 92 and the printed circuit board 93. In some embodiments of the present disclosure, the space 900 may include a package body surrounding the charging element 95. In some embodiments of the present discourse, the printed circuit board 91 may include a square shape in a top view perspective. Since the printed circuit board 91 may include a square shape, the space 900 may have more capacity to receive more components. As shown in FIG. 9, an electronic component 9 is mounted on the printed circuit board 93, and the electronic component 96 and the charging element 95 are disposed side by side. Further, an area of the printed circuit board 93 may be larger than an area of the printed circuit board 91. In other words, the printed circuit board 91 and the interposer 92 cooperatively form a cap mounted on the printed circuit board 93, and the charging element 95 is mounted on the printed circuit board 93 and covered by the cap formed by the printed circuit board 91 and the interposer 92. In other words, the interposer 92 defines an opening to accommodate the charging element 95.

In some embodiments of the present disclosure, the charging element 95 is the same as or similar to the charging element 85. That is, the charging element 95 may include an electromagnet and have a ring-shaped body with coils. Further, the ring-shaped body of the charging element 95 may have a gap.

Meanwhile, the printed circuit board 91 may have an opening substantially aligning with the gap of the charging element 95 and be in communicate with the inner space 900. That is, the opening of the printed circuit board 91 may provide a passage extending from outside of the electronic device 9 into the inside of the electronic device 9. That is, an external device could be put into the electronic device 9 and located at the gap of the charging element 95. When the external device is put into the electronic device 9 and located at the gap of the charging element 95, the charging element 95 is driven to generate the electromagnetic field so that the external device is electrically coupled to the charging element 95 and charged by the electronic device 9.

Referring to FIG. 9, the printed circuit board 91 may include a conductive layer 911 and a dielectric layer 914. In some embodiments of the present disclosure, the conductive layer 911 includes a circuit layer. In some embodiments of the present disclosure, the conductive layer 911 includes a metal layer. In some embodiments of the present disclosure, the conductive layer 911 includes a Cu layer. In some embodiments, the dielectric layer 914 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like.

Moreover, the printed circuit board 91 may include a barrier layer 912. The barrier layer 912 may include a magnetic permeable material. In some embodiments of the present disclosure, the barrier layer 912 includes a conductive material. In some embodiments of the present disclosure, the barrier layer 912 includes a non-conducting material. In some embodiments of the present disclosure, the barrier layer 912 abuts the conductive layer 911. That is, the barrier layer 912 may be embedded in the printed circuit board 91 and covered by the dielectric layer 914. In some embodiments of the present disclosure, the barrier layer 912 is disposed on a surface 916 (e.g., a lower surface) of the printed circuit board 91. That is, the barrier layer 912 may cover the dielectric layer 914 of the printed circuit board 91. Given the above, the barrier layer 912 is arranged between the charging element 95 and the conductive layer 911. The barrier layer 912 may have a substantially circular area. The peripheral of the circular area of the barrier layer 912 may substantially conform to the outer edge of the ring-shaped charging element 95. That is, the barrier layer 912 may fully cover the charging element 95 and an area surrounded by the charging element 95. Thus, in a top view perspective, the barrier layer 912 may overlap the charging element 95. As stated above, the ring-shaped body of the charging element 95 may have the gap, and thus the circular area of the barrier layer 912 may have a blank corresponding to the gap of the charging element 95.

As stated above, when the external device is put into the electronic device 9 and located at the gap of the charging element 95, the charging element 95 is driven to generate the electromagnetic field so that the external device is electrically coupled to the charging element 95 and charged by the electronic device 9. The conductive layer 911 forms an EMI shielding layer which is configured to shield an outside from the electromagnetic field produced by the charging element 95. The magnetic field lines generated from the charging element 95 may reach the barrier layer 912 before reaching the conductive layer 911 since a distance between the charging element 95 and the barrier layer 912 is shorter than a distance between the charging element 95 and the conductive layer 911. Therefore, the barrier layer 912 is configured to collect the magnetic field lines generated from the charging element 95 and thus block the electromagnetic induction effect caused by the electromagnetic field provided from the charging element 95 and the conductive layer 911. Further, the eddy current generated from the electromagnetic induction effect may be reduced. The inductance and quality factor of the charging element 95 may be increased and the charge efficiency of the electronic device 9 may be improved.

The printed circuit board 93 may include a conductive layer 931 and a dielectric layer 934. In some embodiments of the present disclosure, the conductive layer 931 includes a circuit layer. In some embodiments of the present disclosure, the conductive layer 931 includes a metal layer. In some embodiments of the present disclosure, the conductive layer 931 includes a Cu layer. In some embodiments of the present disclosure, the conductive layer 931 includes a ground layer. In some embodiments, the dielectric layer 934 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like.

Moreover, the printed circuit board 93 may include a barrier layer 932. The barrier layer 932 may include a magnetic permeable material. In some embodiments of the present disclosure, the barrier layer 932 includes a conductive material. In some embodiments of the present disclosure, the barrier layer 932 includes a non-conducting material. In some embodiments of the present disclosure, the barrier layer 932 abuts the conductive layer 931. That is, the barrier layer 932 may be embedded in the printed circuit board 93 and covered by the dielectric layer 934. In some embodiments of the present disclosure, the barrier layer 932 is disposed on a surface 935 (e.g., an upper surface) of the printed circuit board 93. That is, the barrier layer 932 may cover the dielectric layer 934 of the printed circuit board 93. Given the above, the barrier layer 932 is arranged between the charging element 95 and the conductive layer 931. The barrier layer 932 may have a substantially circular area. The peripheral of the circular area of the barrier layer 932 may substantially conform to the outer edge of the ring-shaped charging element 95. That is, the barrier layer 932 may fully cover the charging element 95 and an area surrounded by the charging element 95. Thus, in a bottom view perspective, the barrier layer 932 may overlap the charging element 95. As stated above, the ring-shaped body of the charging element 95 may have the gap, and thus the circular area of the barrier layer 932 may have a blank corresponding to the gap of the charging element 95.

As stated above, when the external device is put into the electronic device 9 and located at the gap of the charging element 95, the charging element 95 is driven to generate the electromagnetic field so that the external device is electrically coupled to the charging element 95 and charged by the electronic device 9. The conductive layer 931 forms an EMI shielding layer which is configured to shield an outside from the electromagnetic field produced by the charging element 95. The magnetic field lines generated from the charging element 95 may reach the barrier layer 932 before reaching the conductive layer 931 since a distance between the charging element 95 and the barrier layer 932 is shorter than a distance between the charging element 95 and the conductive layer 931. Therefore, the barrier layer 932 is configured to collect the magnetic field lines generated from the charging element 25 and thus block the electromagnetic induction effect caused by the electromagnetic field provided from the charging element 95 and the conductive layer 931. Further, the eddy current generated from the electromagnetic induction effect may be reduced. The inductance and quality factor of the charging element 95 may be increased and the charge efficiency of the electronic device 9 may be improved.

Referring to FIG. 9, the charging element 95 may be arranged between the printed circuit board 91 with the conductive layer 911 and the printed circuit board 93 with the conductive layer 931. That is, the conductive layer 911 may be above the charging element 95 and the conductive layer 931 may be underneath the charging element 95. Thus, the conductive layer 911 and the conductive layer 931 are configured to accommodate loops of the electromagnetic field generated by the charging element 95.

The interposer 92 is disposed or mounted on the surface 935 of the printed circuit board 93, and is configured to support the printed circuit board 91. The interposer 92 may include an interconnection structure 921 and the dielectric layer 924. In some embodiments, the dielectric layer 924 may include an organic material, a solder mask, a polyimide (PI), an epoxy, an Ajinomoto build-up film (ABF), one or more molding compounds, one or more pre-impregnated composite fibers (e.g., a pre-preg fiber), a borophosphosilicate glass (BPSG), a silicon oxide, a silicon nitride, a silicon oxynitride, an undoped silicate glass (USG), any combination thereof, or the like. In some embodiments of the present disclosure, a plurality of electrical connections 929 is arranged between the surface 935 of the printed circuit board 93 and the interposer 92 so as to electrically connect printed circuit board 93 to the interposer 92. The electrical connection 929 may include a solder ball or a solder bump such as a C4 bump. In some embodiments of the present disclosure, a plurality of electrical connections 928 is arranged between the surface 916 of the printed circuit board 91 and the interposer 92 so as to electrically connect printed circuit board 91 to the interposer 92. The electrical connection 928 may include a solder ball or a solder bump such as a C4 bump. In some embodiments of the present disclosure, the interconnection structure 921 forms an EMI shielding layer. In some embodiments of the present disclosure, the electrical connection 928 and/or the electrical connection 929 may be a part of the EMI shielding layer. In other words, the conductive layers 911, 931, the interconnection structure 921 and the electrical connection 928 and/or the electrical connection 929 are collectively configured to block the electromagnetic field.

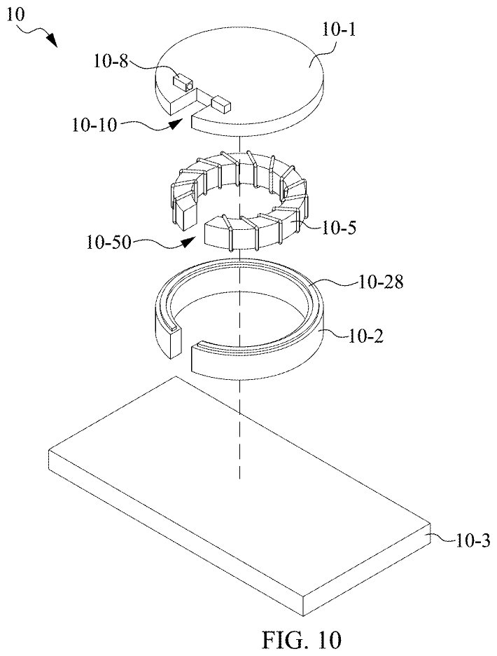

FIG. 10 is an exploded view of an electronic device 10 in accordance with an embodiment of the instant disclosure. Referring to FIG. 1A, the electronic device 10 may include a printed circuit board 10-1 (e.g., an upper circuit board), an interposer 10-2, a printed circuit board 10-3 (e.g., a lower circuit board) and a charging element 10-5. The interposer 10-2 is stacked on the printed circuit board 10-3 and the printed circuit board 10-1 is stacked on the interposer 10-2. That is, the interposer 10-2 is disposed on the printed circuit board 10-3 and supports the printed circuit board 10-1. As the interposer 10-2 is stacked on the printed circuit board 10-3 and the printed circuit board 10-1 is stacked on the interposer 10-2, the printed circuit board 10-1, the interposer 10-2 and the printed circuit board 10-3 may define an inner space. Further, the charging element 10-5 may be arranged within the inner space defined by the printed circuit board 10-1, the interposer 10-2 and the printed circuit board 10-3. In some embodiments of the present disclosure, the inner space cooperatively defined by the printed circuit board 10-1, the interposer 10-2 and the printed circuit board 10-3 may include a package body surrounding the charging element 10-5.

In some embodiments of the present disclosure, the charging element 10-5 includes an electromagnet. In some embodiments of the present disclosure, the charging element 10-5 includes a coil unit. Referring to FIG. 10, the electromagnet may have a ring-shaped body with coils. Further, the ring-shaped body of the charging element 10-5 may have a gap 10-50. That is, the charging element 10-5 includes a breach.

In some embodiments of the present disclosure, an electronic component 10-8 may be mounted or disposed on the printed circuit board 10-1. In some embodiments of the present disclosure, the electronic component 10-8 is an IR sensor.

As shown in FIG. 10, the printed circuit board 11 may have an opening 10-10. The opening 10-10 may substantially align with the gap 10-50 of the charging element 10-5 and be in communicate with the inner space. That is, the opening 10-10 may provide a passage extending from outside of the electronic device 10 into the inside of the electronic device 10.

In some embodiments of the present disclosure, an electrical connections 10-28 is arranged between the printed circuit board 10-1 and the interposer 10-2 and configured to electrically connect the printed circuit board 10-1 to the interposer 10-2.

In some embodiments of the present disclosure, the printed circuit board 10-1 is the same as or similar to the print circuit board 11, 21, 31, 41, 51. In some embodiments of the present disclosure, the interposer 10-2 is the same as or similar to the print circuit board 12, 22, 32, 42, 52. In some embodiments of the present disclosure, the printed circuit board 10-3 is the same as or similar to the print circuit board 13, 23, 33, 43, 53.

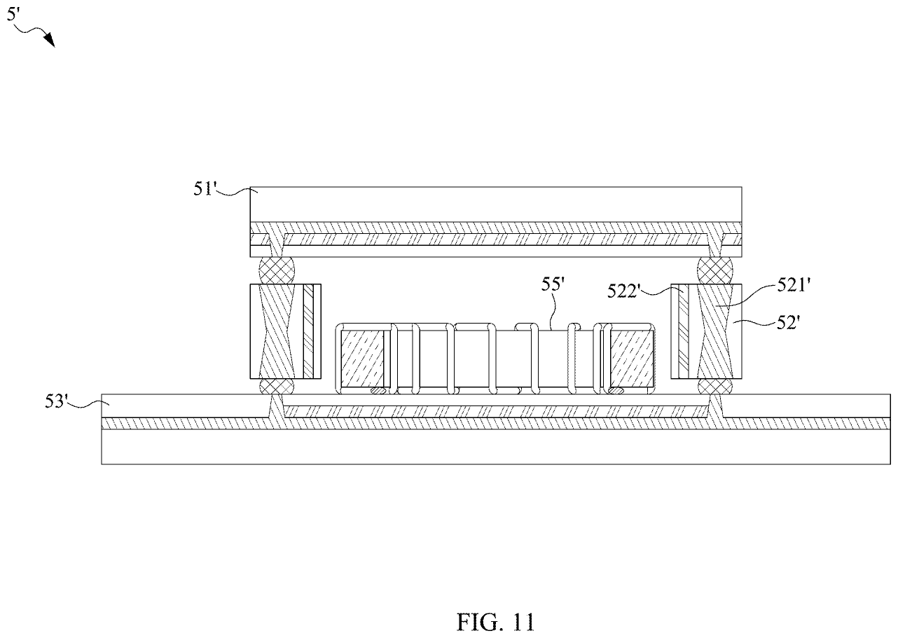

FIG. 11 is a schematic cross-sectional view of an electronic device 5′ in accordance with an embodiment of the instant disclosure. The electronic device 5′ may include a printed circuit board 51′ (e.g., an upper circuit board), an interposer 52′, a printed circuit board 53′ (e.g., a lower circuit board) and a charging element 55′. As shown in FIG. 11, the electronic device 5′ is similar to the electronic device 5 shown in FIGS. 5A and 5B. Iome embodiments of the present disclosure, the printed circuit board 51′ is the same as or similar to the print circuit board 51. In some embodiments of the present disclosure, the printed circuit board 53′ is the same as or similar to the print circuit board 53. Moreover, the interposer 52′ includes a conductive via 521′ and a barrier 522′ embedded in the interposer 52′.

As used herein, the singular terms “a,” “an,” and “the” may include a plurality of referents unless the context clearly dictates otherwise.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to #10% of that numerical value, such as less than or equal to ±5%, less than or equal to ±4%, less than or equal to ±3%, less than or equal to ±2%, less than or equal to #1%, less than or equal to ±0.5%, less than or equal to ±0.1%, or less than or equal to ±0.05%. For example, two numerical values can be deemed to be “substantially” the same or equal if the difference between the values is less than or equal to ±10% of an average of the values, such as less than or equal to ±5%, less than or equal to ±4%, less than or equal to ±3%, less than or equal to ±2%, less than or equal to #1%, less than or equal to ±0.5%, less than or equal to #0.1%, or less than or equal to #0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to =0.05°. For example, “substantially” perpendicular can refer to a range of angular variation relative to 90° that is less than or equal to ±10°, such as less than or equal to ±5°, less than or equal to ±4°, less than or equal to ±3º, less than or equal to ±2°, less than or equal to #1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range were explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein are described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations on the present disclosure.

What is claimed is:

1. An electronic device, comprising:
a coil element configured to provide an electromagnetic field;
a housing comprising an EMI (Electromagnetic Interference) shielding layer and accommodating the coil element; and
a barrier configured to block an electromagnetic induction effect caused by the electromagnetic field and the EMI shielding layer.

2. The electronic device of claim 1, wherein the barrier comprises a magnetic permeable material.

3. The electronic device of claim 1, wherein, in a cross-sectional view, the barrier is disposed adjacent to at least two sides of the coil element.

4. The electronic device of claim 3, in a top view perspective, the barrier substantially surrounds the coil element.

5. The electronic device of claim 1, wherein at least a portion of the barrier is arranged within the housing.

6. The electronic device of claim 1, wherein the housing comprises a first conductive portion and a second conductive portion, and wherein the first conductive portion is arranged over the coil element, the second conductive portion is arranged to be adjacent to at least two sides of the coil element, and wherein the first conductive portion and the second conductive portion are configured to block the electromagnetic field.

7. The electronic device of claim 6, wherein the second conductive portion defines an opening accommodating the coil element, and wherein the first conductive portion covers the coil element and is connected to the second conductive portion through a first solder material.

8. The electronic device of claim 7, wherein the first conductive portion, the second conductive portion and the first solder material are collectively configured to block the electromagnetic field.

9. The electronic device of claim 7, further comprising a circuit board under the coil element and electrically connected to the second conductive portion, wherein the circuit board is configured to block the electromagnetic field.

10. The electronic device of claim 9, wherein the circuit board is connected to the second conductive portion through a second solder material, and wherein the circuit board, the second solder material and the housing are collectively configured to block the electromagnetic field.

11. The electronic device of claim 1, wherein the EMI shielding layer is configured to block an affection by the electromagnetic field to a component disposed outside the surrounding structure.

12. The electronic device of claim 1, wherein the housing has an opening configured to receive an external device being charged by the electromagnetic field.

13. An electronic device, comprising:
a coil element configured to provide an electromagnetic field; and
a EMI (Electromagnetic Interference) shielding structure covering the coil element and comprising a first conductive layer with a plurality of separated portions, wherein the separated portions are configured to reduce an eddy current generated by an electromagnetic induction caused by the electromagnetic field and the EMI shielding structure.

14. The electronic device of claim 13, wherein the EMI shielding structure comprises a second conductive layer, and wherein the first conductive layer is between the second conductive layer and the coil element, and wherein the second conductive layer is configured to block an affection by the electromagnetic field to a component disposed outside the EMI shielding structure.

15. The electronic device of claim 14, wherein, in a cross-sectional view, the second conductive layer covers a gap between the adjacent separated portions of the first conductive layer and configured to block a portion of the electromagnetic field passing through the gap.

16. The electronic device of claim 13, further comprising a barrier between the coil element and the first conductive layer and configured to block an electromagnetic induction effect caused by the electromagnetic field and the EMI shielding structure.

17. An electronic device, comprising:
an inductor;
a conductive structure covering the inductor; and
a magnetic structure arranged between the inductor and the conductive structure;
wherein the magnetic structure is configured to increase an inductance of the inductor.

18. The electronic device of claim 17, wherein the conductive structure comprises a module and a circuit board disposed under the module, and wherein the module comprises:
a top circuit structure;
a bottom circuit structure; and
an interposer between the top circuit structure and the bottom circuit structure;
wherein the circuit board and the module are collectively configured to block an electromagnetic field from the inductor.

19. The electronic device of claim 18, wherein a thickness of the top circuit structure is greater than a thickness of the bottom circuit structure.

20. The electronic device of claim 18, wherein the magnetic structure comprises:
a first magnetic layer, wherein at least a portion of the first magnetic layer is arranged within the top circuit structure;
a second magnetic layer disposed at the interposer; and
a third magnetic layer, wherein at least a portion of the third magnetic layer is arranged within the bottom circuit structure;
wherein the first magnetic layer, the second magnetic layer and the third magnetic layer are collectively configured to collect the electromagnetic field provided from the inductor.
